(19) United States
(12) Patent Application Publication
(10) Pub. No.: US 2002/0041214 A1
(43) Pub. Date: Apr. 11, 2002

(54) PLL circuit

(76) Inventor: Nobuhiko Ichimura, Yamagata (JP)

Correspondence Address: McGinn & Gibb, PLLC, Suite 200, 8321 Old Courthouse Road, Vienna, VA, 22182-3817, US

(21) Appl. No.: 09/964,743

(22) Filed: Sep. 28, 2001

(30) Foreign Application Priority Data
Oct. 5, 2000 (JP) 311730/2000

(51) Int. Cl. H03L 7/093

(52) U.S. Cl. 331/14; 331/17; 331/25; 327/157

(57) ABSTRACT

A PLL circuit is provided wherein it is possible not only to get a high C/N ratio characteristic but also to speed up lock-up time at arbitrary intervals. A current value I_{cp} [Ampere] of an output current signal Icp outputted from a charge pump circuit is switched synchronizing with a timer signal flosw outputted from fast lock timer circuit within a set time set up on the basis of externally inputted dividing ratio setting data. Thereby, when the timer signal flosw outputted from the fast lock timer circuit is on a high level, it is possible to set up the current value I_{cp} [Ampere] supplied to a low-pass filter to a larger current value and speed up the lock-up. On the other hand, when the timer signal flosw outputted from the fast lock timer circuit is on a low level, it is possible to get the current value I_{cp} [Ampere] supplied to the low-pass filter under control to a small current value and get a high C/N ratio.

### BACKGROUND OF THE INVENTION

The present invention relates to a PLL (Phase Locked Loop) circuit, and in particular, to a PLL circuit that switches output current from a charge pump circuit before and after PLL lock-up.

1. Description of the Related Art

Recently, a PLL (Phase Locked Loop) circuit, which is a function element, begins to make a mark in accordance with noticeable breakthrough in technology concerning semiconductor integrated circuits.

This PLL circuit has circuitry that output frequency from a voltage control oscillator and the phase thereof respond to input signal frequency and the phase thereof by utilizing pull-in phenomenon in an oscillator. This circuit is a landmark in that it is possible to conflate analog technology and digital technology.

A PLL frequency synthesizer circuit is one of applications of the PLL circuit suchlike. The PLL frequency synthesizer circuit is typically applied to a mobile communication system, tuners for TV/BS/CS broadcasting and so forth, which serves as an interface leading up to converting information transmitted as analog signals into digital signals.

Especially in a mobile communication system such as a recent cellular phone, there are outstanding movements such as digital communicating and multi channeling. With these movements, commencing with downsizing/low electric power, coping with data communication and speeding up at switching channels and so forth are also required of the PLL circuit.

In order to meet these requirement, in the PLL circuit, it is necessary to speed up switching timing of output current in a charge pump circuit, which exerts a strong influence on speeding up frequency lock-up time until frequency becomes stable after channel switching.

FIG. 1 shows conventional circuitry of the PLL circuit. In reference to FIG. 1, the conventional PLL circuit comprises:

a quartz oscillator 100 which outputs a base signal fs having frequency fₛ [Hz];

a divider (1/R) 200 which divides the base signal fs outputted from the quartz oscillator 100 by R and generates a reference signal fs/R;

a phase comparing detector (PD) 300 which generates voltage (phase difference signals PDU and PDD) corresponding to a phase difference between inputted two kinds of signals (the reference signal fs/R and an oscillation dividing signal f0/N);

a charge pump circuit (CP) 400 for storing charge in a capacitor set up in low-pass filter (LPF) 500;

the low-pass filter (LPF) 500 which eliminates high frequency components in an output current signal Icp inputted from the charge pump circuit 400 and shapes its waveform;

a voltage control oscillator (VCO) 600 which oscillates according to a voltage value of a control voltage signal CC inputted from the low-pass filter 500;

a programmable divider (1/N) 700 which divides an oscillation signal f0 having frequency f₀ [Hz] outputted from the VOC 600 by N by applying dividing number N according to instructions from the outside;

a data interface 800 which sets a dividing value N in the programmable divider 700; and

a lock detector circuit (LOCK) 900 which detects whether or not the two kinds of signals (the reference signal fs/R and the oscillation dividing signal f0/N) inputted into the phase comparing detector (PD) 300 are synchronized.

In this configuration, the phase comparing detector 300 compares the reference signal fs/R having the frequency fₛ/R [Hz], which is outputted from the quartz oscillator 100 and divided by R in the divider 200, with the oscillation dividing signal f0/N having the frequency f₀/N [Hz], which is outputted from the voltage control oscillator 600 and divided by N in the programmable divider 700. According to the result of the comparison, the phase comparing detector 300 outputs the phase difference signals PDU and PDD.

After the phase difference signals PDU and PDD are inputted into the charge pump circuit 400, the charge pump circuit 400 switches a current value I_{cp} [Ampere] of an output current signal Icp on the basis of a fixed cycle lock signal Iosw inputted from the lock detector circuit 900.

After that, the high frequency components in the output current signal Icp are eliminated, and the output current signal Icp turns the waveform-shaped control voltage signal CC of the voltage value CC [V] by the low-pass filter 500. Then the output current signal Icp is inputted into the voltage control oscillator 600.

In this way, the PLL circuit shown in FIG. 1 executes PLL control by method of correcting the control voltage signal CC inputted into the voltage control oscillator 600 on the basis of the phase difference between the reference signal fs/R having the frequency fₛ/R [Hz], which is obtained by dividing the base signal fs having the frequency fₛ [Hz] by R, and the oscillation dividing signal f0/N having the frequency f₀/N [Hz], which is obtained by dividing the oscillation signal f0 having the frequency f₀ [Hz] outputted from the voltage control oscillator 600 by N, in the phase comparing detector 300.

The PLL circuit having the above configuration is importantly characterized by frequency lock-up time, that is, frequency stability time which dissolves phase difference which arises from switching channels (frequency), and a carrier noise ratio showing purity of the normal signal in the oscillation signal f0 outputted from the voltage control oscillator 600, that is, a C/N ratio.

The both characteristics of the frequency lock-up time and a C/N ratio depend on damping factor in the PLL circuit. The damping factor is found by the current value I_{cp} [Ampere] of the output current signal Icp from the charge pump circuit 400, a filter constant in the low-pass filter 500, a dividing ratio N in the programmable divider 700 and so forth.

Therefore, in the case of increasing the current value I_{cp} [Ampere] of the output current signal Icp from the charge pump circuit 400, the damping factor increases because the capacitor configuring the low-pass filter 500 charges/discharges rapidly. On the other hand, in the case of reducing the current value I_{cp} [Ampere] of the output current signal Icp, the damping factor reduces because the above-described capacitor charges/discharges slowly.

Here, when the damping factor in the PLL circuit is large, the PLL circuit comes into a stable state rapidly. Thereby, the lock-up time quickens. However, in the transient state wherein the PLL circuit comes into the stable state rapidly, the state of the PLL circuit violently changes. Thereby, a lot of noise components generate, and the C/N ratio changes for worse.

On the other hand, when the damping factor in the PLL circuit is small, the PLL circuit comes into the stable state slowly. Thereby the lock-up time gets longer. However, in the transient state, the state of the PLL circuit changes slowly. Thereby, the generated noise components are reduced, and the C/N ratio is improved.

As described above, relations between speeding up the lock-up time and improving the high C/N ratio are generally opposite to each other.

Therefore, in order to meet the both characteristics at the same time, prior arts have tried to improve the high-speed switching before PLL lock-up and noise characteristic after PLL lock-up.

[Explanation of Conventional Charge Pump Circuit]

Next will be an explanation of the charge pump circuit 400 for operating as above by using FIG. 2.

As shown in FIG. 2, in the conventional charge pump circuit 400, P-MOSFET Q401 is set up on an input port of the phase difference signal PDU outputted from the phase comparing detector 300. Besides, N-MOSFET Q 402 is set up through an inverter INV401 on an input port of the phase difference signal PDD outputted from the phase comparing detector 300.

Here, the board of the P-MOSFET Q401 is connected to a source. The source is connected to a power supply voltage V through a galvano static circuit I4002. Besides, the board of the N-MOSFET Q402 is connected to a source. The source is grounded through a galvano static source I4003.

Further, the charge pump circuit 400 comprises a switch SW4010 which switches according to the lock signal Iosw outputted from the lock detector circuit 900, a galvano static circuit I4001 whose one side is connected to the switch SW4010 and whose other side is grounded, and a galvano static circuit I4000 which is set up in parallel with the switch SW4010 and the galvano static circuit I4001.

Besides, one side of the switch SW 4010, which is not connected to the galvano static circuit I4001, and one side of the galvano static circuit I4000, which is not grounded, are connected to the input sides of the galvano static circuits I4002 and I4003, respectively. According to current passing through the galvano static circuits I4000 and I4001, current conducted the galvano static circuits I4002 and I4003 are regulated.

By this configuring as above, the conventional charge pump circuit 400 operates as shown in FIG. 3. That is, in unlocked state (SW4010: ON) where the lock signal Iosw is inputted from the lock detector circuit 900 into the switch SW4010, the charge pump circuit 400 outputs current value (I4000+I4001) calculated by adding the current I4001 passing through the galvano static circuit I4001 and the current I4000 passing through the galvano static circuit I4000 to the low-pass filter 500 as the output current signal Icp. On the other hand, in locked state (SW4010: OFF) where the lock signal Iosw is not inputted from the lock detector circuit 900 into the switch SW4010, the charge pump circuit 400 outputs only current value I4000 passing through the galvano static circuit I4000 to the low-pass filter 500 as the output current signal Icp. By switching the current value I_{cp} [Ampere] of the output current signal Icp as described above, it is possible to get favorable characteristic.

Therefore, in unlock state, supply current outputted from the charge pump circuit 400 is set up at larger value. Thereby, the lock-up time is cut down. On the other hand, in locked state, the amount of the supply current is reduced much smaller. Thereby, it is possible to get favorable C/N characteristic.

However, in the conventional PLL circuit, the timing of switching the output current I_{cp} outputted from the charge pump circuit 400 is set up by applying the lock signal Iosw outputted with constant cycle from the lock detector 900. Thereby, the supply current during definite period of time is switched. Therefore, it is impossible to arbitrarily set up time according to a condition of the phase difference between the two kinds of signals. Consequently, setting up the filter constant in the low-pass filter 500, which is an external filter, largely depends on the damping factor, and it is difficult to be satisfied with the lock-up time and the C/N characteristic.

Further, in the conventional PLL circuit, by the same reason as described above, there is no choice but to set up time length at a fixed value in unlocked state. Thereby it is impossible to set up the most appropriate damping factor according to a loop gain shift in unlock state.

### SUMMARY OF THE INVENTION

It is therefore an object of the present invention to provide a PLL circuit wherein it is possible to make sure of high C/N characteristic by configuring the switching of output current from a charge pump circuit so as to be set up with a cycle according to states of phase between two kinds of signals from phase comparing detector. Besides, it is therefore another object of the present invention to provide a PLL circuit wherein it is possible to speed up lock-up time by setting up time arbitrarily.

According to a first aspect of the present invention, for achieving the objects mentioned above, there is provided a PLL circuit comprising:

a phase comparing means which outputs phase difference signals on the basis of phase difference of inputted two signals;

a charge pump circuit which outputs an output current signal on the basis of the phase difference signals; and

a fast lock timer circuit which outputs a signal for switching a value of the output current signal outputted from the charge pump means, wherein:

the fast lock timer circuit outputs a timer signal for lock-up or lock to the charge pump in order to switch the value of the output current signal.

According to a second aspect of the present invention, the PLL circuit switches an unlock period, which is a lock-up getting a high C/N ratio, and a lock period getting high-speed lock-up at arbitrary intervals on the basis of the output current signal.

According to a third aspect of the present invention, the PLL circuit further includes a low-pass filter and an oscillator control means, wherein the fast lock timer circuit switches the value of the output current signal from the charge pump circuit at arbitrary intervals by counting a base signal divided according to an inputted dividing ratio setting data and gets speeding up of lock-up time and a high C/N ratio characteristic.

According to a fourth aspect of the present invention, the PLL further includes:

a data interface means which directs the fast lock timer means to switch the value of the output current signal on the basis of inputted data;

a voltage control oscillation means which outputs an oscillation signal on the basis of an oscillator control signal outputted from the low-pass filter; and

a programmable counter which divides the oscillation signal by an arbitrary dividing value, wherein;

the fast lock timer means outputs a signal for switching the value of the output current value on the basis of the direction.

Further, it is preferable that:

the fast lock timer further includes a filter switching means which outputs a signal for switching prescribed loop-bandwidth in the low-pass filter; and

the low-pass filter includes a first filter means and a second filter means which are connected in parallel, wherein the signal outputted from the filter switching means is inputted into an input port of the second filter through a first resistor, the second filter means includes the first resistor, a second resistor and a capacitor, the first and second resistors are connected in parallel with the first filter means through the capacitor, the first and second resistors are connected to the capacitor in parallel, and the second resistor is grounded, besides it is preferable that:

the filter switching means switches the prescribed loop-bandwidth according as the current value of the output current signal is switched;

the data interface means includes:

a shift register receiving a clock signal and synchronizing with an externally signal, inputting a data signal on the basis of the synchronization, and outputting the inputted data signal to the fast lock timer means; and

an enable counter specifying at least one part of the data signal outputted from the shift register, and further outputting a latch/reset signal which specifies a timing of switching value of the output current signal;

the fast lock timer means includes:

a data latch means latching the inputted data signal on the basis of the latch/reset signal outputted form the enable counter means, and outputs at least one count value setting signal; and

a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;

the programmable counter has three inputs and one output, in which two inputs among the three inputs are for an enable signal input and the divided base signal input, including:

a plurality of pairs of NAND circuits and a plurality of flip-flop circuits that are same number of the pairs of NAND circuits, set up on an input port of the enable signal from the data interface;

a first NAND circuit and a second inversion circuit set up on an input port of the divided base signal through a first inversion circuit, wherein:

remaining one input among the three inputs is for a signal input from the data latch, which is inputted through one NAND circuit forming the pairs of NAND circuits set up on the output port of the enable signal;

the one output includes a third NAND circuit into which all \overline{Q} outputs of the flip-flops are inputted;

the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;

each of the output from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} outputs is inputted into each Cp in a post flip-flop through a second NAND circuit in a second stage and a fourth inversion circuit in a fourth stage, the divided base signal from the first NAND circuit and the second inversion circuit is inputted into a CP in a flip flop in a first stage through a third inversion circuits and a fourth inversion circuit in a fourth stage, which is set in a post stage of the third inversion circuit; and

an output from the third NAND circuit is inputted into the second NAND circuit.

In particular, it is preferable that the flip-flop circuits are set/reset-D-flip-flops.

Further, it is preferable that:

the charge pump includes a switch comprising an N-MOSFET;

the timer signal is inputted into a gate of the N-MOSFET;

the charge pump includes the switch and connected two galvano static circuits in parallel;

one of the two-galvano static circuits is connected to the switch in series; and

the switch outputs current through at least one of the galvano static circuits on the basis of the timer signal.

Further, it is preferable that the phase comparing means includes:

a plurality of first NAND circuits into which the inputted two signals are inputted, respectively;

a plurality of reset/set-flip-flops;

a second NAND circuit whose input side is connected to each output port of the first NAND circuits and each output port of reset/set-flip-flops;

a plurality of third NAND circuits whose input sides are connected to each output port of the first NAND circuits, each output port of the reset/set-flip-flops, and an output port of the second NAND circuit, wherein:

each output port of the third NAND circuits is connected to each input port of the first NAND circuits; and

two signals which are to be inputted into the charge pump are outputted from each output port of the third NAND circuit.

Besides, it is preferable that the dividing ratio setting data applied in this kind of PLL circuit includes:

a clock signal for synchronizing with an external signal;

a data signal for specifying interval of switching the current value of the output current signal; and

an enable signal for switching the current value of the output current signal.

Further, it is preferable that reset or latch for switching frequency of the base signal is specified on the basis of the enable signal.

### BRIEF DESCRIPTION OF THE DRAWINGS

The objects and features of the present invention will become more apparent from the consideration of the following detailed description taken in conjunction with the accompanying drawings in which:

FIG. 1 is a block diagram showing a configuration of a conventional PLL circuit;

FIG. 2 is a circuit diagram showing circuitry of a conventional charge pump circuit 400;

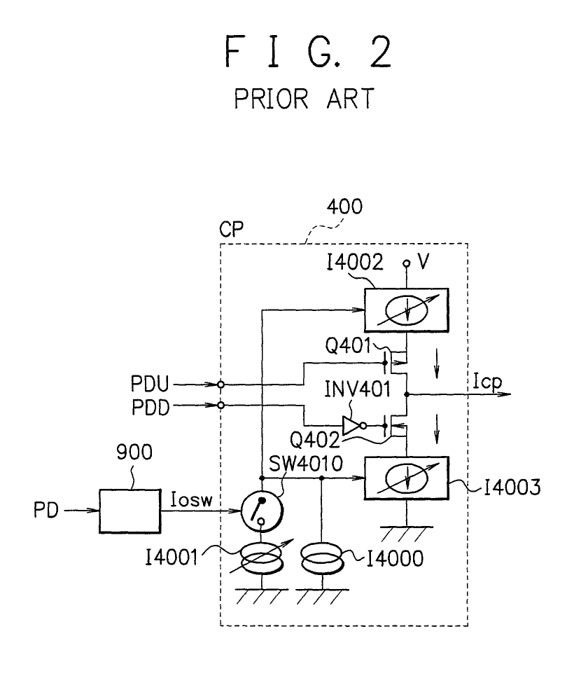

FIG. 3 is a timing chart showing time and motion of each signal in the conventional PLL circuit;

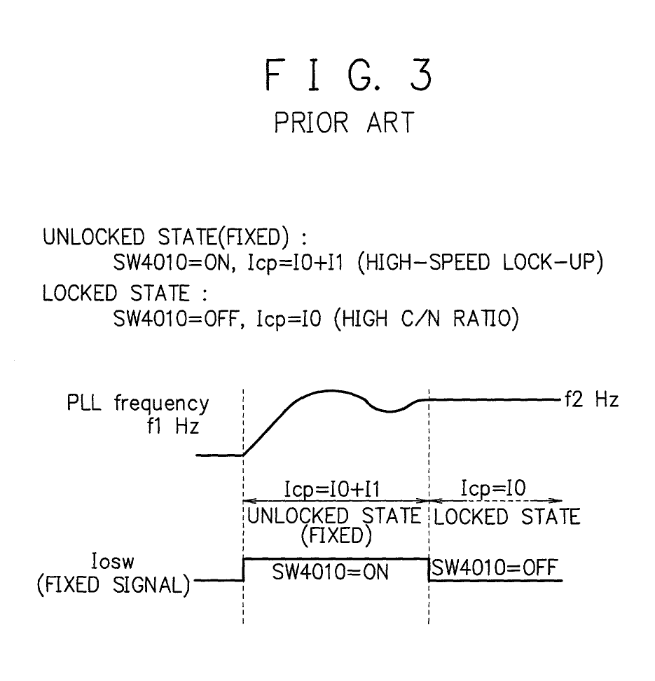

FIG. 4 is a block diagram showing a configuration of a PLL circuit according to a first embodiment of the present invention;

FIG. 5 is a circuit diagram showing circuitry of a generally applied phase comparing detector 1;

FIG. 6 is a timing chart showing phase difference signals PDU and PDD, which are outputted from the phase comparing detector 1 shown in FIG. 5 when a reference signal fs/R and an oscillation dividing signal f0/N are inputted into the phase comparing detector 1, and an output current signal Icp, which is outputted from a charge pump circuit 2;

FIG. 7 is a circuit diagram showing circuitry of the charge pump circuit 2 according to the first embodiment of the present invention;

FIG. 8 is a circuit diagram showing an example of circuitry of a programmable counter PC 1 configuring a fast lock timer circuit 7 according to the first embodiment of the present invention;

FIG. 9 is a timing chart showing time and motion of each signal according to the first embodiment of the present invention;

FIG. 10 is a timing chart showing circuit operation of the programmable counter PC1 configuring the fast lock timer circuit 7, and further showing operation in the case where a count value M is set up as M=8 according to the first embodiment of the present invention;

FIG. 11 is a timing chart showing circuit operation of the programmable counter PC1 configuring the fast lock timer circuit 7, and further showing operation in the case where a count value M is set up as M=1 according to the first embodiment of the present invention;

FIG. 12 is a timing chart showing circuit operation of the programmable counter PC1 configuring the fast lock timer circuit 7, and further showing operation in the case where a count value M is set up as M=15 according to the first embodiment of the present invention;

FIG. 13 is a block diagram showing a PLL circuit according to a second embodiment of the present invention;

FIG. 14 is a circuit diagram showing circuitry of a charge pump circuit 2, low-pass filter 13 and fast lock timer circuit 17 according to the second embodiment of the present invention;

FIG. 15 is a graph showing phase noise characteristic and lock-up time dependence for frequency of loop-bandwidth; and

FIG. 16 is a timing chart showing time and motion of each signal according to the second embodiment of the present invention.

### DESCRIPTION OF THE PREFERRED EMBODIMENTS

Referring now to the drawings, an embodiment of the present invention is explained in detail.

According to the present invention, a PLL circuit, which switches current supply from a charge pump circuit (CP) to a low-pass filter (LPF), is characterized by setting up a fast lock timer circuit that switches the current before and after a phase of an input signal (hereinafter referred to as a base signal) and a phase of a signal oscillated by a voltage control oscillator (VCO) in the PLL circuit are synchronized (locked in).

The PLL circuit counts the base signal, which is divided by R (R is a fixed dividing ratio), at arbitrary dividing number. Thereby, it becomes possible to switch the output current from the charge pump circuit at arbitrary time, supply sufficient current to the low-pass filter set up in the post stage of the fast lock timer at lock-up, and supply sufficient current to the low-pass filter at locked.

By this configuration of the PLL circuit of the present invention, it is possible to set up a process of pulling in a signal from the voltage control oscillator to the base signal at arbitrary time. Thereby, it becomes possible to accelerate and fine control lock-up time regardless of a filter constant of the low-pass filter. The following will be an explanation in detail of the PLL circuit according to the present invention by using drawings.

[First Embodiment]

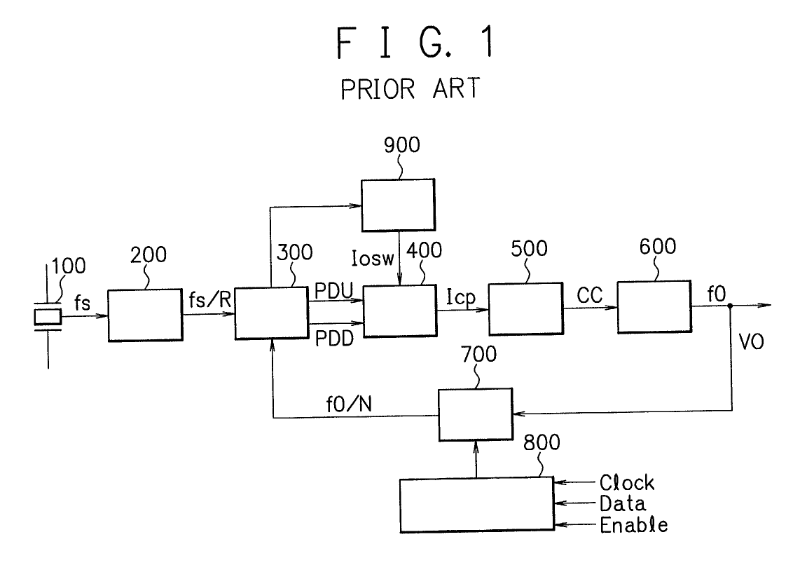

First of all, there is an explanation in detail of a first embodiment of the present invention by using drawings. FIG. 1 is a block diagram showing configuration of a PLL circuit according to the first embodiment of the present invention.

[Whole Configuration of First Embodiment]

[Configuration of PLL Circuit]

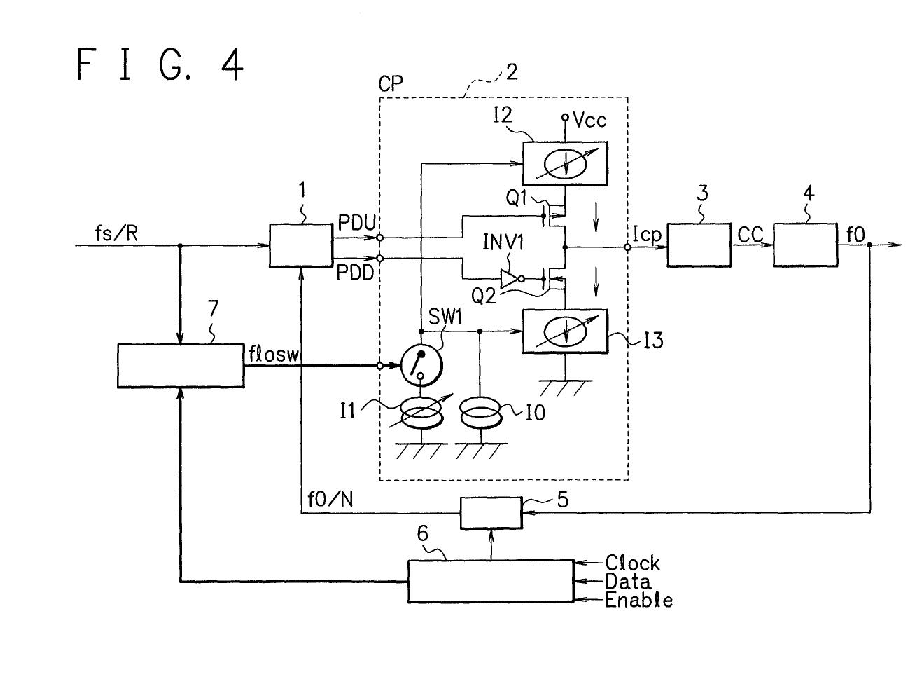

In reference to FIG. 4, a PLL circuit of the present invention comprises:

a phase comparing detector (PD) 1 which compares phases of inputted two kinds of signals and outputs voltage as phase difference signals PDU and PDD on the basis of the result of the above comparison;

a charge pump circuit (CD) 2 which outputs output current signal Icp having various current value on the basis of the signals PDU and PDD inputted from the phase comparing detector 1;

a low-pass filter (LPF) 3 which eliminates high frequency components in the output current signal Icp outputted from the charge pump circuit 2 by an integral process, shapes its waveform into direct current (DC) components, and outputs the waveform-shaped signal Icp as an oscillator control signal CC;

a voltage control oscillator (VCO) 4 which outputs an oscillation signal f0 on the basis of the oscillator control signal CC outputted from the low-pass filter 3;

a programmable divider (1/N) 5 which divides the oscillation signal f0 inputted from the voltage control oscillator 4 by N by applying externally inputted arbitrary dividing number N;

a data interface 6 which sets up the externally directed dividing number N to the programmable divider 5; and

a fast lock timer circuit 7 which converts the current value of the output current signal Icp outputted from the charge pump circuit 2 on the basis of an externally directed count value M.

In the above configuration, the two kinds of signals means a reference signal fs/R having frequency fₛ/R [Hz], which is found by dividing a base signal fs having frequency fₛ [Hz] inputted from the outside of the PLL circuit shown in FIG. 4 by dividing number R, and an oscillation dividing signal f0/N having frequency f₀/N [Hz], which is outputted from the programmable divider 5. The phase comparing detector 1 compares a phase of the reference signal fs/R and that of the oscillation dividing signal f0/N. On the basis of the result of the comparison, the phase comparing detector 1 outputs the phase difference signals PDU and PDD.

[Configuration of Phase Comparing Detector 1]

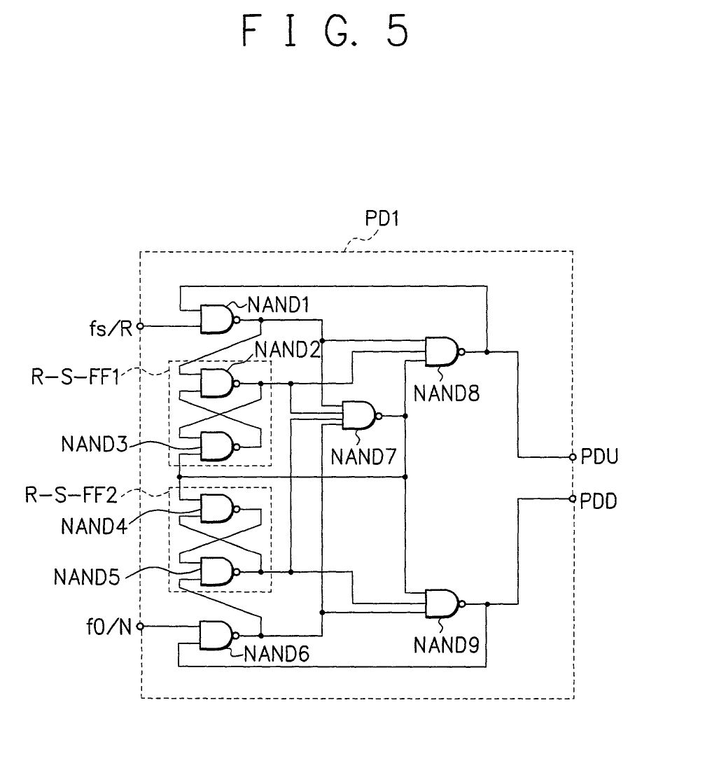

As shown in FIG. 5, the phase comparing detector 1 applied in this embodiment comprises nine NAND gates NAND 1 to NAND 9. Incidentally, the phase comparing detector 1 applied in this embodiment may be the one which is generally applied.

In this configuration, the NAND gates NAND 2 and NAND 3, and NAND 4 and NAND 5 form reset/set-flip-flops R-S-FF 1 and R-S-FF 2, respectively. By this configuration, it is possible to prevent chattering generated by signals outputted from NAND gates NAND 1 and NAND 2, respectively.

Chattering means noise voltage generated at switching a low level “L” (namely, and a high level “H” each other in the case where machinelike contact points are applied. This kind of chattering causes malfunction at switching.

By this means, the phase comparing detector 1 applied in the present invention can eliminate the chattering generated when positive and negative of the two kinds of the inputted signals (fs/R and f0/N) counterchanges by applying the four NAND gates NAND 2 to NAND 5 connected as a reset/set-flip-flop type, respectively.

The output from the reset/set-flip-flops R-S-FF1 and R-S-FF2 configured like above is inputted into NAND gates NAND 7, NAND 8, and NAND 9, respectively.

Besides, as shown in FIG. 5 the two input ports of the NAND gate NAND 7 are connected to the output ports of the NAND 1 and NAND 6, respectively. The other two ports are connected to the output ports of the R-S FF 1 and R-S FF 2, respectively. The output port of the NAND 7 is connected to the input ports of the NAND 8 and NAND 9, and the R-S-FF 1 and R-S-FF 2. Besides, the output ports of the NAND 8 and NAND 9 are connected to the input ports of the NAND 1 and NAND 6, respectively.

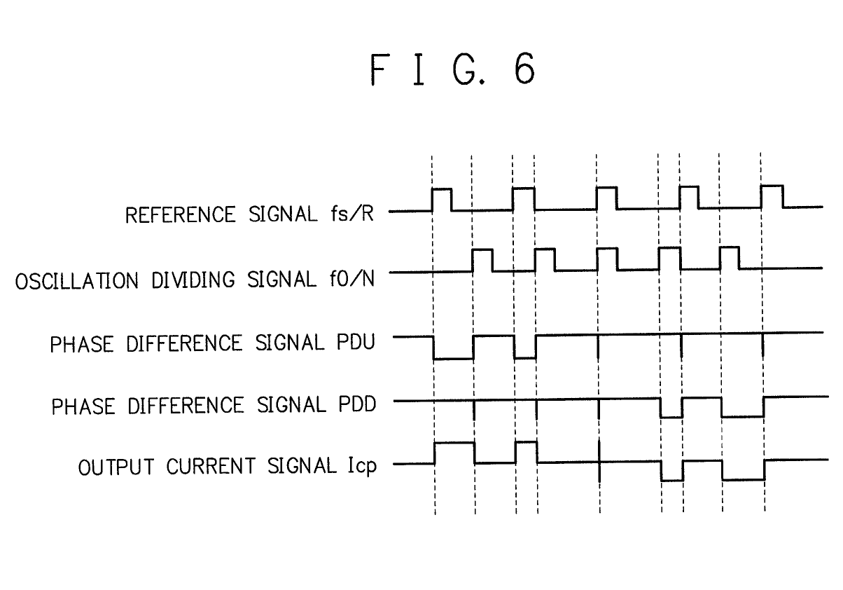

In this configuration, for example, when the two kinds of signals having different phases shown in FIG. 6 (the reference signal fs/R and the oscillation dividing signal f0/N) are inputted into the phase comparing detector 1, the phase difference signals PDU and PDD outputted from the phase comparing detector 1 shown in FIG. 5 comes to the ones shown in FIG. 6. After that, the outputted phase difference signals PDU and PDD are inputted into the charge pump circuit 2, respectively as shown in FIG. 4.

As shown in FIG. 4, the charge pump circuit 2 applied in the present invention comprises an inverter INV 1 set up on the output port of the phase difference signal PDD, and further comprises a P-MOSFET Q1, a N-MOSFET Q2, galvano static circuits I0, I1, I2 and I3, and a switch SW1.

[Configuration of Charge Pump Circuit 2]

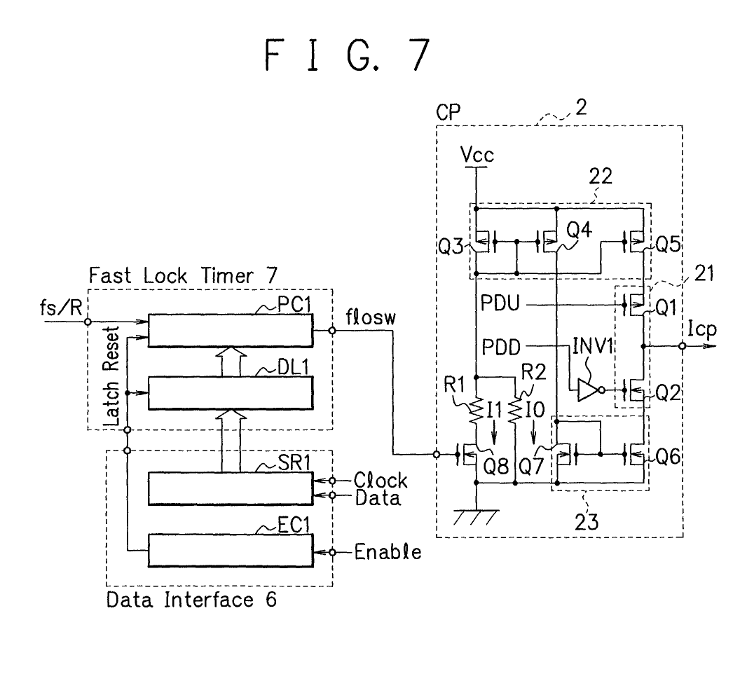

A circuit example of the charge pump circuit 2 having the above configuration is shown in FIG. 7 in detail.

In the charge pump circuit 2 applied in the present invention as shown in FIG. 7, the P-MOS type FET Q1 is set up on the input port of the phase difference signal PDU. Besides, the inverter INV1 is set up on the input port of the phase difference signal PDD. By setting up the inverter INV1 on the output port of the phase different signal PDD,- it is possible to invert the voltage of the inputted phase difference signal PDD, which is inputted into the gate electrode of the N-MOS type FET Q2 set up on the post port thereof.

The charge pump circuit 2 applied in this embodiment further comprises three P-MOSFETs Q3, Q4 and Q5, three N-MOSFETs Q6, Q7 and Q8, and resistors R1 and R2.

In this configuration, the P-MOSFET Q1 and the N-MOSFET Q2 constitute a C-MOS type impedance transformation circuit 21, whose drains are connected each other. In the impedance transformation circuit 21, input impedance is practically infinite. On the other hand, output impedance is switched at ON (continue)/OFF (shutdown) state.

Besides, the P-MOSFETs Q3, Q4 and Q5 constitute a current mirror type galvano static circuit 22, whose gates are connected each other, corresponding to the galvano static circuit I2 shown in FIG. 4. The galvano static circuit 22 serves as a load resistance of the above-described impedance transformation circuit 21 and serves as output impedance when the P-MOSFET Q1 is on state, which operates in order to supply constant current in outputting.

Moreover, the drain of the P-MOSFET Q4 constituting the galvano static circuit 22 is connected to the gates of the N-MOSFETs Q6 and Q7, which constitute a galvano static circuit 23, and the drain of the N-MOSFET Q7.

The galvano static circuit 23 corresponds to the galvano static circuit I3 shown in FIG. 4. The galvano static circuit 23 also serves as a load resistance of the above described impedance transformation circuit 21 and serves as output impedance when the N-MOSFET Q6 is on state, which operates in order to supply constant current in outputting.

Further, the N-MOSFET Q8 constitutes the switch SW1 shown in FIG. 4. When a timer signal flosw is inputted from the external fast lock timer 7 into the N-MOSFET Q8, it comes to on state wherein current is passed through the resistor R1.

The resistors R1 and R2 constitutes the galvano static circuit I0 and I1 shown in FIG. 4, respectively. Current I₁ passes through the resistor R1 and I₀ passes through R2, respectively.

Therefore, when the timer signal flosw is inputted from the fast lock timer 7 into the charge pump circuit 2, the absolute value of the current passing through the galvano static circuit 22 comes to current I₀+I₁. On the other hand, when the timer signal flosw is not inputted, the absolute value of the current passing through the galvano static circuit 22 comes to current I₀.

When the phase difference signal PDU is inputted from the phase difference detector PD1, the charge pump circuit 2 operates so as to output positive current. On the other hand, when the phase difference signal PDD is inputted, the charge pump circuit 2 operates in order to outputs negative current.

Therefore, in the state where the timer signal flosw is inputted from the fast lock timer 7, when the phase difference signal PDU is inputted from the phase comparing detector 1, the current value of the output current signal Icp outputted from the charge pump circuit 2 is the sum of the current passing through the resistors R1 and R2 (I₀+I₁). On the other hand, when the phase difference signal PDD is inputted from the phase comparing detector 1, the current value of the output current signal Icp outputted from the charge pump circuit 2 is the negative value of the sum of the current passing through the resistors R1 and R2 (−(I₀+I₁)).

In the meantime, in the state where the timer signal flosw is not inputted from the fast lock timer 7, when the phase difference signal PDU is inputted from the phase comparing detector 1, the current value of the output current signal Icp outputted from the charge pump circuit 2 is the current passing through the resistor R2 (I₀). On the other hand, when the phase difference signal PDD is inputted from the phase comparing detector 1, the current value of the output current signal Icp outputted from the charge pump circuit 2 is the negative value of the current passing through the resistor R1 (−I₁).

[Signal Outputted from Phase Comparing Detector 1 and Signal Outputted from The Charge Pump Circuit 2]

Next will be an explanation of the output current signal Icp outputted form the charge pump circuit 2 by using FIG. 6. Concerning with the timer signal flosw, there is no mention of the explanation by using FIG. 6 here, however, it will be explained later.

The two kinds of signals inputted into the phase comparing detector 1 are shown as the reference signal fs/R and the oscillation dividing signal f0/N for convenience of explanation. When the phase of the oscillation dividing signal f0/N is delaying compared to that of the reference signal fs/R, the phase difference signal PDU outputted from the phase comparing detector 1 gets down at the timing when the reference signal fs/R rises, and shows a “L” (low) level only during a time corresponding to the phase difference thereof. In this case, the phase difference signal PDD keeps an “H” (high) level.

On the other hand, when the oscillation dividing signal f0/N is leading compared to that of the reference signal fs/R, the phase difference signal PDD outputted from the phase comparing detector 1 gets down at the timing when the oscillation dividing signal f0/N rises, and shows the “L” level only during a time corresponding to the phase difference thereof. In this case, the phase difference signal PDU keeps the “H” level.

When the reference signal fs/R and the oscillation dividing signal f0/N are in phase at each rising, both of the phase difference signals PDU and PDD show the “H” level, which shows a state where the PLL is locked.

Therefore, concerning the outputted two kinds of the phase difference signals PDU and PDD as described above, the phase difference signal PDU is inputted into the gate of the P-MOSFET Q1 in the charge pump circuit 2. On the other hand, the phase difference signal PDD, after the voltage level thereof is inverted at the inverter INV1, is inputted into the gate of the N-MOFET Q2.

By inputting the phase difference signal PDU into the gate, when the phase difference signal PDU is on the “L” level, that is, when the phase of the oscillation dividing signal f0/N lags that of the reference signal fs/R, the P-MOSFET Q1 in the charge pump circuit 2 comes to on state and outputs the current supplied from the galvano static circuit 12 as the output current signal Icp.

Besides, by inputting the phase difference signal PDD into the gate, which was inverted at the inverter INV1, when the phase difference signal PDD is on the “L” level, that is, when the phase of the reference signal fs/R lags that of the oscillation dividing signal f0/N, the N-MOSFET Q2 in the charge pump circuit 2 comes to on state and outputs the current supplied from the galvano static circuit I3 as the output current I_{cp}.

Incidentally, the current supplied from the galvano static circuit 13 is negative current. Therefore, as shown in FIG. 6, the output current signal Icp outputted from the charge pump circuit 2 is positive one when the P-MOSFET Q1 is in on state. On the other hand, the output signal Icp is negative one when the N-MOSFET Q2 is in on state.

As shown in FIG. 4, the outputted output current signal Icp is inputted into the low-pass filter 3, and an integral process is executed to the signal. By the integral process, the high frequency components in the output current signal Icp are eliminated, whose waveform is shaped into direct current components, and outputted as oscillator control signal CC whose voltage level is CC [V].

As described above, it is apparent that the oscillation signal f0 outputted from the voltage control oscillator 4 is based on the phase difference between the two kinds of signals from the phase comparing detector 1.

Besides, the oscillation signal f0 outputted from the voltage control oscillator 4 is inputted into the programmable divider 5. The programmable divider 5 decides the dividing number N by a signal inputted from the data interface 6, and divides the oscillation signal f0 by N. Therefore, the phase comparing detector 1 is configured so as to compare the reference signal fs/R found by dividing the base signal fs by R and the oscillation dividing signal f0/N found by dividing the oscillation signal f0 by N. This shows that the frequency ratio between the two kinds of signals, which are synchronized practically, comes to N/R in the PLL circuit according to this embodiment.

[Configuration of Data Interface 6]

FIG. 7 shows a configuration of the data interface 6.

As shown in FIG. 7, the data interface 6 applied in this embodiment comprises a shift register SR1 and an enable counter EC1. A clock signal Clock and data signals Data are inputted to the shift register SR1. An enable signal Enable is inputted into the enable counter (EC1). The dividing number N and the count value M set up in the programmable divider 5 and the fast lock timer circuit 7 by these dividing ratio setting data are arbitrary number and value. These number and value may be set up on the basis of the result of monitoring frequency outputted from the PLL circuit applied in this embodiment, or may be set up according to conditions beforehand.

Besides, the above-described dividing ratio setting data comprises the clock signal Clock for bit synchronization between the data interface 6 and the external configuration, the data signals (signal) consisting of serial data with k bit, and the enable signal Enable specifying available components of the data signals.

The shift register SR1 operates so as to find out the bit synchronization with outside on the basis of the externally inputted clock signal Clock and input the data signals Data according to the synchronization. In parallel with the operation, the shift register SR1 operates so as to judge the available components in the inputted data signals Data according to the enable signal Enable inputted into the enable counter EC1, and so as to decide the dividing number N that are to be set up in the programmable divider 5.

In other wards, the data interface 6 picks up data for setting up the dividing number N in the programmable divider 5 and data for setting up the count value M in the fast lock timer circuit 7 from the data signals Data received by the shift register SR1 in the fast clock timer circuit 7, and outputs each data to the programmable divider 5 and the fast lock timer 7 shown in FIG. 4. In parallel with the operation, the data interface 6 outputs the enable signal Enable received by the enable counter EC1 to the above-described programmable divider 5 and the fast lock timer circuit 7 as a latch signal Latch or a reset signal Reset.

By this means, the dividing number N of the oscillation dividing signal f0/N is set up in the programmable divider 5 applied in this embodiment. Besides, the count value M of the reference signal fs/R is set up in the fast lock timer circuit 7 as described later.

In the above explanation, the dividing number N set up in the programmable divider 5 and the count value M set up in the fast lock timer circuit 7 are both found on the basis of the same dividing ratio setting data. In setting up these number and value through the data interface 6, according to this embodiment, there is shown a configuration that a data area for setting up the dividing number N and a data area for setting up the count value M have different bit area, respectively. This kind of data “bit” configuration is often applied in prior arts. Thereby, the explanation of the data configuration in this embodiment will be abbreviated.

According to the present invention, the current level of the output current signal Icp outputted from the charge pump 2 is switched at frequency pulling-in (unlocked state) and when it is in phase (at locked state). In other wards, at unlocked (lock-up) state, relatively high current is run out from the charge pump circuit 2. On the other hand, at locked state, relatively low current is run out. By this configuration, it becomes possible to cut down lock-up time and gain high C/N characteristic.

[Configuration of Fast Lock Timer Circuit 7]

In order to switch the current value supplied to the low-pass filter 3 at unlocked state and locked state as described above, the fast lock timer circuit 7 is newly set up in the PLL circuit in the first embodiment. As shown in FIG. 7, the fast lock timer circuit 7 comprises a data latched circuit DL1 and a programmable counter PC1. The data latch circuit DL1 stores the dividing ratio setting data inputted from the data interface 6. The programmable counter PC1 consists of n bit, stores data (dividing ratio setting data) latched by the data latch circuit DL1, and sets up the count value M on the basis of the stored data. The first lock timer circuit 7 receives the latched data Latch outputted from the shift register SR1 in the data interface 6 at the data latch circuit DL1. On the basis of the latched data, the fast lock timer circuit 7 operates so as to get the programmable counter PC1 to count the inputted reference signal fs/R.

In this operation, the signal Enable inputted into the enable counter EC1 functions as the latch signal Latch specifying the available components in the latch data, which is sent to the data latch circuit DL1, and the reset signal Reset resetting the count value M set up in the programmable counter PC1, which is sent to the programmable counter PC1.

Further, a signal setting up the count value M in the programmable counter PC1, which is outputted from the above-described data latch circuit DL1, is shown as a count value setting signal FLK as described later. Incidentally in the following explanation, the maximum count value set up in the programmable counter PC1 is set up as “15”. Therefore, in this embodiment, there is an explanation that the count value setting signal FLK is shown as the count value setting signals FLK1 to FLK4.

[Configuration of Programmable Counter PC1]

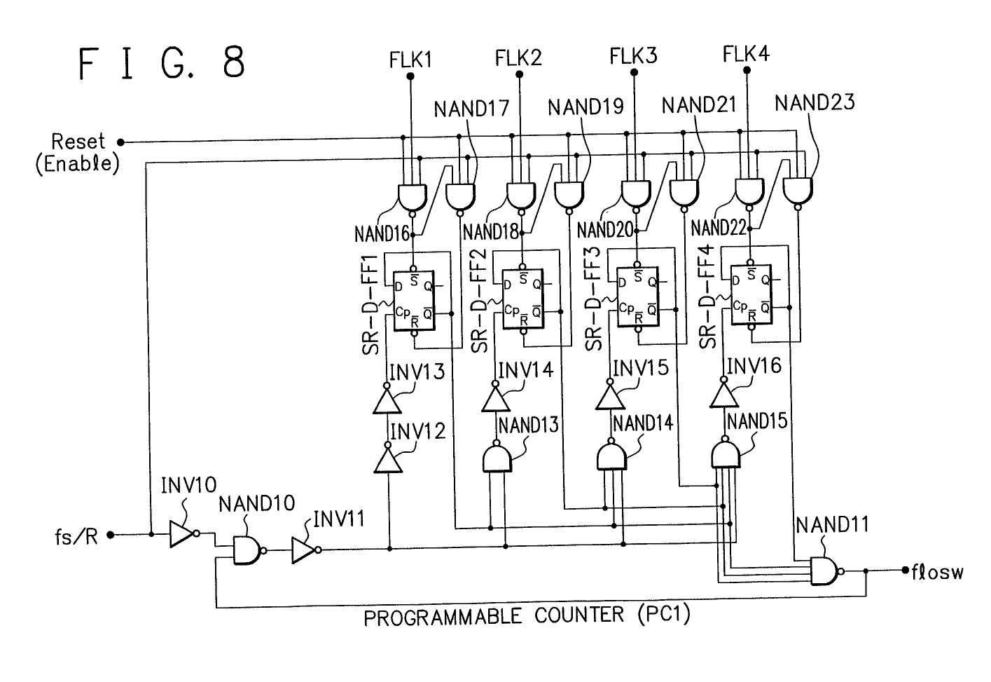

The following is a circuit example of the programmable counter PC1 configuring the above-described fast lock timer circuit 7 by using FIG. 8. As shown in FIG. 8, the programmable counter PC1 applied in this embodiment has two input signals. The enable signal Enable as the reset signal is inputted into one, and the reference signal fs/R, which is a target of the count, is inputted into the other.

The reference signal fs/R inputted as above branches. One of the branching signals is inputted into an inverter INV10, and the rest of the branching signal is inputted into NAND circuits NAND 16 to NAND 23, respectively.

The reference signal fs/R of the branching signal inputted into the inverter INV10 is inputted into an inverter INV11 through the NAND circuit NAND 10. After that, the reference signal fs/R outputted from the inverter INV11 branches the following four signals as shown in FIG. 8. The first signal is inputted into a Cp input in a set/reset-D-flip-flop SR-D-FF1 through inverters INV12 and INV13. The second signal is inputted into a Cp input in a set/reset-D-flip-flop SR-D-FF2 through an inverter INV14 after a NAND circuit NAND13 calculates a logical product between the second signal and a \overline{Q} output in the set/reset-D-flip-flop SR-D-FF1. The third signal is inputted into a Cp input in a set/reset-D-flip-flop SR-D-FF3 through an inverter 15 after a NAND circuit NAND14 calculates a logical product between the third signal and \overline{Q} outputs in the set/reset-D-flip-flop SR-D-FF1 and the set/reset-D-flip-flop SR-D-FF2. The fourth signal is inputted into a Cp input in a set/reset-D-flip-flop SR-D-FF4 through an inverter 16 after a NAND circuit NAND15 calculates a logical product between the fourth signal and \overline{Q} outputs in the set/reset-D-flip-flop SR-D-FF1, set/reset-D-flip-flop SR-D-FF2 and set/reset-D-flip-flop SR-D-FF3.

Besides, in the example shown in FIG. 8, the enable signal Enable is inputted into the NAND circuits NAND 16 to NAND 23, respectively as well.

The count value setting signals FLK1, FLK2, FLK3 and FLK4 outputted from the data latch circuit DL1 are inputted into the NAND circuits NAND16, NAND18, NAND20, and NAND22, respectively in the above configuration. The count value setting signals FLK1, FLK2, FLK3 and FLK4 outputted from the data latch circuit DL1 are the signals Data that the data signals, which are received through the shift register SR1 in the data interface 6 by the data latch circuit DL1, are latched, respectively. The latched data signals are inputted into the programmable counter PC1 as described above as the count value setting signals FLK1 to FLK4 through leased lines (buses).

In the example of configuration of the programmable counter PC1 shown in FIG. 8, the maximum count value set up as the count value M is set up as “15”, and the programmable counter PC1 is configured so that the count value M comes to natural numbers from “1” to “15” by the count value setting signals FLK1 to FLK4. In other words, when “1” is inputted as the count value setting signal FLK1, “1” is added to a count number m. When “1” is inputted as the count value setting signal FLK2, “2” is added to the count number m. When “1” is inputted as the count value setting signal FLK3, “4” is added to the count number m. Further, when “1” is inputted as the count value setting signal FLK4, “8” is added to the count number m. Therefore, the count number m set up in the programmable counter PC1 is set up so that the count value M comes to natural numbers from “1” to “15” by the combination of these added values. For example, when the count value M is set up as “1” is inputted into the count value setting signal FLK1 only. For another example, when the count value M is set up as “M=15”, “1” is inputted into all of the count value setting signals FLK1 to FLK4. Incidentally, “M=0” means that all of the count value setting signals FLK1 to FLK4 is 0 (unchanged: no reset). Therefore, the “M=0” shows that no FLK signal is generated.

Besides, each of the signals outputted form the NAND circuits NAND16, NAND18, NAND20 and NAND22 is inverted and inputted into each of the S inputs in the set/reset-D-flip-flops SR-D-FF1 to SR-D-FF4 connected thereto, respectively. In the same way, each of the signals outputted form the NAND circuits NAND17, NAND19, NAND21 and NAND23 is inverted and inputted into each of the R inputs in the set/reset-D-flip-flops SR-D-FF1 to SR-D-FF4 connected thereto, respectively.

Further, each of the signals outputted form the inverters INV13, INV14, INV15 and INV16 is inputted into each of the Cp inputs in the set/reset-D-flip-flops SR-D-FF1 to SR-D-FF4. Besides each of the D inputs in the same set/reset-D-flip-flops SR-D-FF1 to SR-D-FF4 is connected to each of the \overline{Q} outputs in the same set/reset-D-flip-flops SR-D-FF1 to SR-D-FF4. Each of the \overline{Q} outputs is inputted into each of the D inputs.

Further, a NAND circuit NAND 11 calculates the logical product of the signals outputted from each of the \overline{Q} outputs in each of the same set/reset-D-flip-flops SR-D-FF1 to SR-D-FF4. Then, the inverted value of the logical product is outputted as the output signal (timer signal) flosw from the fast lock timer circuit 7 as shown in FIG. 8.

By this configuration, in the fast lock timer circuit 7, the programmable counter PC1 counts the number of the rise of the reference signal fs/R by setting the start point as the rise of the enable signal Enable inputted from the data interface 6. Then the timer signal flosw is outputted to the charge pump circuit 2 until the number of the rise arrives at the set-up count number m.

Besides, the timer signal flosw is inputted into the gate of the N-MOSFET Q8 consisting of the switch SW1. Thereby, the absolute value of the current of the output current signal Icp outputted from the charge pump circuit 2 comes to |I₀+I₁|.

In this embodiment, the current value I_{cp} [Ampere] of the output current signal Icp outputted from the charge pump circuit 2 is switched synchronizing with the timer signal flosw outputted from the fast lock timer circuit 7. In other wards, when the timer signal flosw is on the high level, the current I_{cp} [Ampere] supplied from the charge pump circuit 2 to the low-pass filter 3 is set to large value. Thereby, it becomes possible to cut down the lock-up time. On the contrary, when the timer signal is on the low level, the current I_{cp} [Ampere] supplied from the charge pump circuit 2 to the low-pass filter 3 is set to small value. Thereby, is becomes possible to get high C/N characteristic.

[Operation According to the First Embodiment]

In the following, a description will be given in detail of operation according to the first embodiment mentioned above with reference to the drawings.

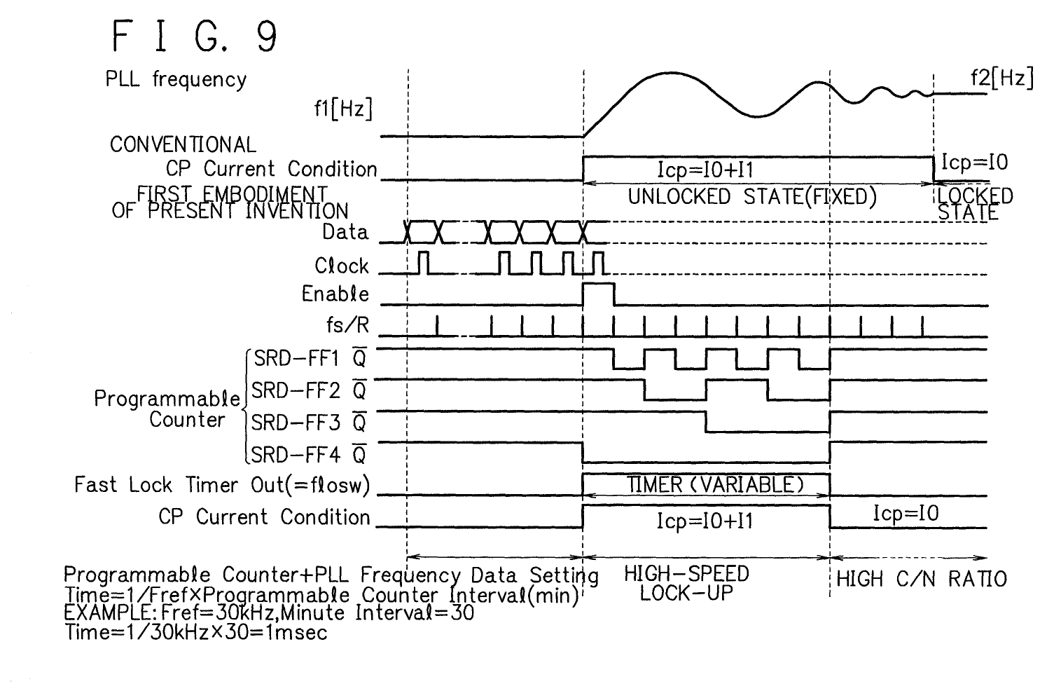

The operation of the first embodiment will be explained first with a timing chart shown in FIG. 9.

FIG. 9 is a timing chart showing time and motion of operation of each signal in the first embodiment. In FIG. 9, “PLL Frequency” indicates the frequency of a base signal fs. In this description, there is explained the case where the channel frequency to which a PLL circuit is to be tuned, namely, the channel frequency of a reference signal fs/R, which is obtained by dividing a base signal fs by R, is switched from f₁ [Hz] to f₂ [Hz].

In addition, “Conventional CP Current Condition” shown in FIG. 9 indicates a transition in current values of a signal outputted from the charge pump circuit 400 of the PLL circuit shown in FIG. 1. In the conventional charge pump circuit 400, when the channel frequency of a reference signal fs/R changes to f₁ [Hz] or f₂ [Hz], the PLL circuit is switched to an unlocked state. During the unlocked state, relatively high electrical current is outputted from the charge pump circuit 400 so that current value of a signal outputted from the charge pump circuit 400 is to be restricted after the PLL circuit enters into a locked state. Therefore, in the structure of the conventional PLL circuit, a relatively high electrical current is supplied to the LPF 500 even at the stage immediately before the lock-up converges on a stable state, and thus high-speedability in lock-up time is hindered.

“Data”, “Clock” and “Enable” shown in FIG. 9 are included in dividing ratio setting data inputted from an external device as is explained above. Those are signals for deciding a dividing number (dividing ratio) N for the programmable divider 5 and a count value M for the fast lock timer circuit 7 in FIG. 4. In the above description, the data signal Data is inputted to the data interface 6 shown in FIG. 4 from an external device simultaneously with the clock signal Clock before the process for switching the channel frequency, to which a PLL circuit is to be tuned, from f₁ [Hz] to f₂ [Hz].

Subsequently, with respect to the inputted data signal Data, data for setting a dividing number N of the programmable divider 5 and data for setting a count value M of the fast lock timer circuit 7 are outputted to the programmable divider 5 and the fast lock timer circuit 7, respectively. Having received the data outputted for respective settings, the programmable divider 5 sets up the dividing number N for dividing an oscillation signal f0 and the fast lock timer circuit 7 sets up the count value M for counting a reference signal fs/R.

As is shown in FIG. 9, the dividing number N and the count value M set at the programmable divider 5 and the fast lock timer circuit 7 become effective at the point of time when an enable signal Enable is inputted to respective circuits (the programmable divider 5 and the fast lock timer circuit 7) from the data interface 6 afterwards. Thereby dividing of the oscillation signal f0 and count of the reference signal fs/R are commenced at the programmable divider 5 and the fast lock timer circuit 7, respectively. Incidentally, as can be seen from FIG. 9, the timing of inputting the enable signal Enable to the programmable counter PC1 is synchronized with the timing of switching the frequency that the oscillation signal f0 has to lock from F₁ [Hz] to F₂ [Hz]. Accordingly, the charge pump circuit 2 of the first embodiment can switch the current value of an output current signal Icp simultaneously with the timing in which the frequency of the oscillation signal f0 is switched.

After the count value M is set up, the fast lock timer circuit 7 outputs a timer signal flosw to a switch SW1 of the charge pump circuit 2 until the count number m of the reference signal fs/R comes to the count value M set as above. Thereby the current value of an output current signal Icp fed to the LPF 3 from the charge pump circuit 2 is switched to a relatively large value (|I₀+I₁|).

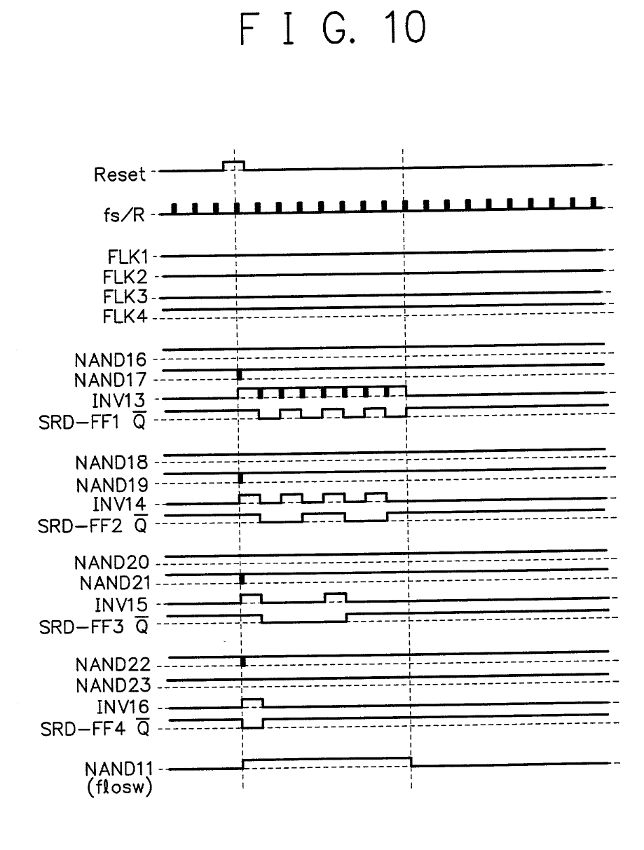

“SR-D-FF1 \overline{Q}”, “SR-D-FF2 \overline{Q}”, “SR-D-FF3 Q”, and “SR-D-FF4 \overline{Q}” in FIG. 9 are output signals from \overline{Q} outputs of set/reset-D-flip-flops constituting the programmable counter PC1 of the fast lock timer circuit 7. In the following, a description will be given in detail of the circuit operation of the programmable counter PC1 included in the fast lock timer circuit 7 with reference to FIGS. 8 and 10.

[Operation of Programmable Counter PC1 (M =8)]

In this description, the case where the programmable counter PC1 is set to count 8 cycles of a reference signal fs/R is taken as an example to explain the operation of the programmable counter PC1 in the fast lock timer circuit 7 according to the present embodiment.

In order to achieve such setting, it is necessary that the set/reset-D-flip-flops SR-D-FF1 to SR-D-FF4 that constitute the programmable counter PC1 operate based on purposes according to data signals (referred to as signals FLK1 to FLK4 in the present embodiment) outputted from the data latch circuit DL1 in the fast lock timer circuit 7. That is, for the programmable counter PC1 of the present embodiment, the count value setting signal FLK4 needs to be inputted as “1”, and the other count value setting signals FLK1 to FLK3 need to be inputted as “0”. Accordingly, the count value M is set to “8” at the programmable counter PC1. The operation for setting the count value M will be explained below by referring to FIG. 10.

In FIG. 10, it is provided to explain an operation example in this embodiment that, with respect to the signals FLK1 to FLK4 outputted from the data latch circuit DL1, the respective signals FLK1 to FLK3 are low-level signals (“0”), and the signal FLK4 is a high-level signal (“1”).

Under the condition that the signals FLK1 to FLK4 have been inputted, when an enable signal Enable is inputted as a reset signal Reset, NAND circuits NAND16, NAND18 and NAND20 output “1” in every period. On the other hand, a NAND circuit NAND22 outputs “0” in a period when a reference signal fs/R as well as the reset signal Reset are “1”, and outputs “1” in other periods.

Concurrently, NAND circuits NAND17, NAND19 and NAND21 output “0” in a period when a reference signal fs/R as well as the reset signal Reset are “1”, and output “1” in other periods. On the other hand, a NAND circuit NAND23 outputs “1” in every period.

In terms of the outputs from the respective NAND circuits NAND16 to NAND23, the outputs from the NAND circuits NAND16, NAND18, NAND20 and NAND22 are fed to \overline{S} inputs of the respective set/reset-D-flip-flops SR-D-FF1 to SR-D-FF4, while the outputs from the NAND circuits NAND17, NAND19, NAND21 and NAND23 are fed to \overline{R} inputs of the respective set/reset-D-flip-flops SR-D-FF1 to SR-D-FF4.

Incidentally, each of the \overline{S} inputs and \overline{R} inputs has a NAND circuit at its gate, where an inputted signal is inverted on the occasion of reception.

Consequently, with respect to the voltage level from each NAND circuit recognized on the side of the set/reset-D-flip-flops SR-D-FF1 to SR-D-FF4, \overline{S} inputs are “0” in every period, while the \overline{R} inputs are “1” during a period when a reference signal fs/R as well as a reset signal Reset are “1”, and “0” in other periods on the side of the set/reset-D-flip-flops SR-D-FF1 to SR-D-FF3. In contrast thereto, on the side of the set/reset-D-flip-flops SR-D-FF4, \overline{S} inputs are “1” for during a period when a reference signal fs/R as well as the reset signal Reset are “1”, and “0” in other periods.

On receipt of signals, first the set/reset-D-flip-flops SR-D-FF1 to SR-D-FF3 set \overline{Q} outputs to “1”, and the set/reset-D-flip-flop SR-D-FF4 sets a \overline{Q} output to “0”.

After that, since an “INV13” outputted from an inverter INV13 is inputted to a Cp input of the set/reset-D-flip-flop SR-D-FF1 as a strobe signal, a signal outputted from the \overline{Q} output of the set/reset-D-flip-flop SR-D-FF1 responds to the down edge of the “INV13” as “SR-D-FF1 \overline{Q}” in FIG. 10, and thereby the voltage level of the signal “SR-D-FF1 \overline{Q}” is switched between “1” and “0”. Thus cycles of the reference signal fs/R are substantially divided by 2.

Next, the NAND circuit NAND13 derives the logical product of the output signal “SRD-FF1 \overline{Q}” from the \overline{Q} output of the set/reset-D-flip-flop SR-D-FF1 and the reference signal fs/R. The “SRD-FF1 \overline{Q}” is then inputted to a Cp input of the set/reset-D-flip-flop SR-D-FF2 as a strobe signal via an inverter INV14. This signal corresponds to “INV14” in FIG. 10. The set/reset-D-flip-flop SR-D-FF2 switches a signal “SRD-FF2 \overline{Q}” to be outputted from the \overline{Q} output from “1” to “0”, or from “0” to “1” according to the down edge of the signal “INV14”.

The NAND circuit NAND14 obtains the logical product of the signal “SRD-FF2 \overline{Q}” outputted in this manner, the reference signal fs/R and the signal “SRD-FF1 \overline{Q}”. Subsequently, the signal “SRD-FF2 \overline{Q}” is inputted to a Cp input as a strobe signal for the set/reset-D-flip-flop SR-D-FF3 via an inverter INV15. This signal corresponds to “INV15” in FIG. 10. The set/reset-D-flip-flop SR-D-FF3 switches a signal “SRD-FF3 \overline{Q}” to be outputted from the \overline{Q} output from “1” to “0”, or from “0” to “1” according to the down edge of the signal “INV15”.

Further, the NAND circuit NAND 15 obtains the logical product of the signal “SRD-FF3 \overline{Q}” outputted as above, the reference signal fs/R, and the signals “SRD-FF1 \overline{Q}” and “SRD-FF2 \overline{Q}” outputted from the \overline{Q} each of the set/reset-D-flip-flops SR-D-FF1 and SR-D-FF2, respectively. Then the signal “SRD-FF3 \overline{Q}” is supplied to a Cp input as a strobe signal of the set/reset-D-flip-flop SR-D-FF4 via an inverter INV16. This signal corresponds to “INV16” in FIG. 10. The set/reset-D-flip-flop SR-D-FF4 switches a signal “SRD-FF4 \overline{Q}” to be outputted from the \overline{Q} output from “1” to “0”, or from “0” to “1” according to the down edge of the signal “INV16”.

Next, the signals “SRD-FF1 \overline{Q}” to “SRD-FF4 \overline{Q}” outputted from the respective set/reset-D-flip-flops are inputted to the NAND circuit NAND11 to obtain the logical product of the respective signals, which is then outputted as a timer signal flosw being an output of the fast lock timer circuit 7.

On this occasion, the logical product of the signals “SRD-FF1 \overline{Q}” to “SRD-FF4 \overline{Q}” is “0”, namely, a period of cycle time of the reference signal fs/R multiplied by 8 (or a period of 8 cycles). Therefore, the inverted value of this is “1”, namely, a period of cycle time of the reference signal fs/R multiplied by 8.

Therefore, in this example operation, only when the “SRD-FF4 \overline{Q}” is “0”, the timer signal flosw outputted from the NAND circuit NAND11 is “1”.

In addition, the timer signal flosw corresponds to “Fast Lock Timer Out (=flosw)” in FIG. 9. The above configuration is clearly explained in that during a period when a timer signal flosw is being outputted (on a high level), the current I_{cp} of an output current signal Icp from the charge pump circuit 2 is expressed as I_{cp}=I₀+I₁, and the current I_{cp} of an output current signal Icp in another period is expressed as I_{cp}=I₀ as is shown in FIG. 9. Besides, a transition in current values of the output current signal Icp outputted from the charge pump circuit 2 is indicated by “CP current Condition” in FIG. 9.

According to the above configuration, the data interface 6 decides a dividing number N and a count value M to be set at the programmable divider 5 and the fast lock timer circuit 7, respectively based on an inputted data signal, and outputs the decided dividing number N to the programmable divider 5 and the fast lock timer circuit 7. On the other hand, the fast lock timer circuit 7, where the count value M is set as above, initializes the count number m in the programmable counter PC1 in response to the rising edge of an enable signal that is inputted from the enable counter EC1 of the data interface 6 to newly commence a count. Subsequently, the fast lock timer circuit 7 outputs a timer signal flosw until “M” cycles of the reference signal fs/R are counted.

In a PLL circuit according to the present embodiment, while an output current signal Icp is on a high level (I_{cp}=I₀+I₁), namely, while the fast lock timer circuit 7 is outputting a timer signal flosw, it is intended to speed up the lock-up. On the contrary, while an output current signal Icp is on a low level (I_{cp}=I₀), namely, while the fast lock timer circuit 7 is not outputting a timer signal flosw, it is intended to achieve a high C/N ratio.

FIG. 9 is a timing chart showing the case where 8 is set as the above-mentioned count value M (M =8). By using an n bit output signal of the programmable counter PC1, the output signal from the programmable counter PC1 is to be an output signal flosw (=timer signal) of the fast lock timer circuit 7. On this occasion, the setting time T of the fast lock timer circuit 7 is expressed by {1/(the frequency of a reference signal)}×M, in short, T={1/(fs/R)}×M.

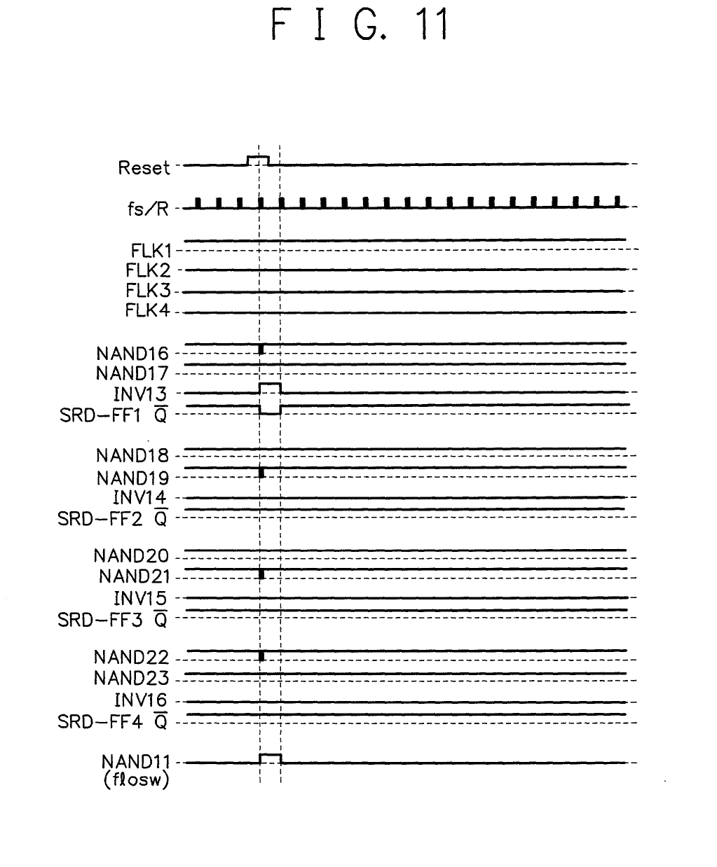

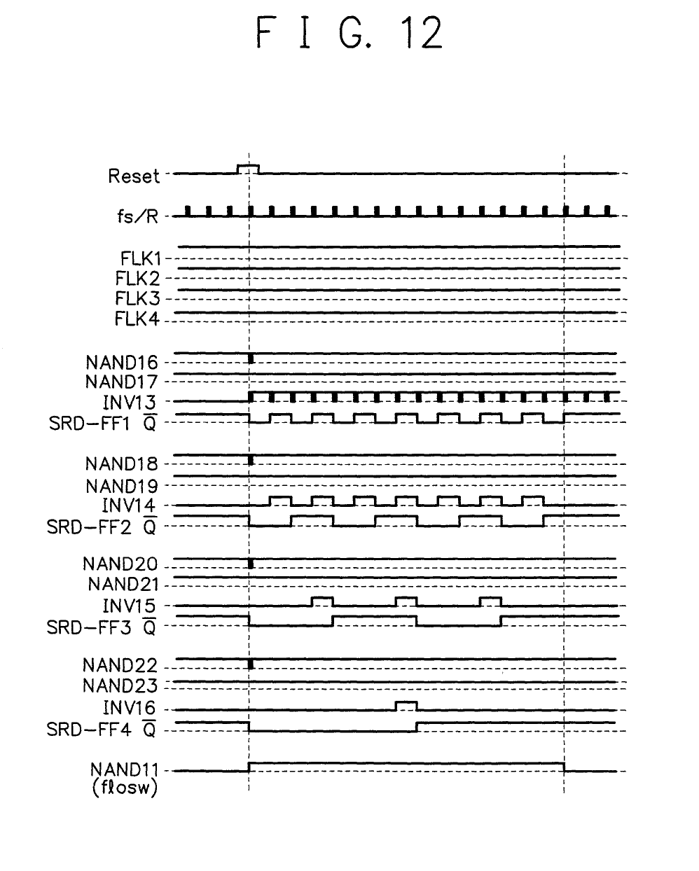

In the above description, the case where the count value M set at the programmable counter PC1 of the fast lock timer circuit 7 is 8 (M=8) has been explained. In the following, explanations are given of respective operations of the programmable counter PC1 when the count value M is set to, for example, 1 (M=1), and 15 (M=15) in detail with reference to FIGS. 11 and 12.

[Operation of Programmable Counter PC1 (M=1)]

For instance, when the count value M=1 is set at the programmable counter PC1 shown in FIG. 8, with respect to the count value setting signals FLK1 to FLK4, only the signal FLK1 is set to “1” and the other signals FLK2 to FLK3 are set to “0” as shown in FIG. 11.

Therefore, in this setting, a signal inputted to the S input of the set/reset-D-flip-flop SR-D-FF1, namely, the signal outputted from the NAND circuit NAND16 is “1” during a period when a reference signal fs/R is “1” while a reset signal Reset is being inputted, and “0” in other periods.

On the other hand, signals inputted to the \overline{S} inputs of the set/reset-D-flip-flops SR-D-FF2 to SR-D-FF4, namely, signals outputted from the NAND circuits NAND18, NAND20 and NAND22 are “1” in every period.

In addition, a signal inputted to the \overline{R} input of the set/reset-D-flip-flop SR-D-FF1, namely, the signal outputted from the NAND circuit NAND17 is “0” during a period when a reference signal fs/R as well as a reset signal Reset are being inputted, and “1” in other periods.

On the other hand, signals inputted to the \overline{R} inputs of the set/reset-D-flip-flops SR-D-FF2 to SR-D-FF4, namely, signals outputted from the NAND circuits NAND19, NAND21 and NAND23 are “1” in every period.

Consequently, an output signal “SRD-FF1 \overline{Q}” outputted from the \overline{Q} output of the set/reset-D-flip-flop SR-D-FF1 is fixed to “0” according to the event that the signal inputted to the S input becomes “1”. Besides, output signals “SRD-FF2 \overline{Q}” to “SRD-FF4 \overline{Q}” outputted from the \overline{Q} outputs of the respective set/reset-D-flip-flops SR-D-FF2 to SR-D-FF4 are fixed to “1” according to the event that the signals inputted to the R input becomes “1”.

Subsequently, the signal outputted from \overline{Q} output of the set/reset-D-flip-flop SR-D-FF1 is inverted to “1” in response to the inverter INV13, namely, the rising of the reference signal fs/R. After the logical product of the inverted signal “SRD-FF1 \overline{Q}” and the reference signal fs/R is derived, the “SRD-FF1 \overline{Q}” is inputted to the Cp input of the set/reset-D-flip-flop SR-D-FF2 as a strobe signal (output of the inverter INV14).

In contrast thereto, an input of the Cp input of the set/reset-D-flip-flop SR-D-FF2, that is, a signal “INV14” outputted from the inverter INV14 is “0” in every period, and therefore, the signal “SRD-FF2 \overline{Q}” outputted from the \overline{Q} output of the set/reset-D-flip-flop SR-D-FF2 is fixed to “1” and unchanged.

Additionally, with respect to the set/reset-D-flip-flops SR-D-FF3 and SR-D-FF4, a signal inputted as a strobe signal to the Cp input of each is “0” in every period. Therefore, the signals outputted from the \overline{Q} outputs each of the set/reset-D-flip-flops SR-D-FF3 and SR-D-FF4 are fixed to “1” and unchanged.

As is described above, as an output wave of the NAND circuit NAND11 that outputs the inverted value of the logical product of signals outputted from \overline{Q} outputs of the respective set/reset-D-flip-flops SR-D-FF1 to SR-D-FF4, “1” is outputted in a period of one cycle time of a reference signal fs/R. That is, in this operation example, a timer signal flosw from the programmable counter PC1 is being outputted as long as a period of one cycle time of a reference signal fs/R. This indicates that when all of the count value setting signals FLK1 to FLK4 are set to “1”, the count value M set at the programmable counter PC1 is “1” (M=1).

[Operation of Programmable Counter PC1 (M=15)]

Next, when the count value M=15 is set at the programmable counter PC1 will be explained referring to FIG. 12.

In this case, all the count value setting signals FLK1 to FLK4 inputted from the data latch circuit DL1 are set to “1”.

Therefore, in this example, signals inputted to the S inputs of the set/reset-D-flip-flops SR-D-FF1 to SR-D-FF4, namely, signals outputted from the NAND circuits NAND16, NAND18, NAND20 and NAND22 are “1” during a period when a reference signal fs/R is “1” while a reset signal Reset is being inputted, and “0” in other periods.

Besides, signals inputted to the \overline{R} inputs of the set/reset-D-flip-flops SR-D-FF1 to SR-D-FF4, namely, signals outputted from the NAND circuit NAND17, NAND19, NAND21 and NAND23 are “1” in every period.

Here, signals recognized at the respective \overline{S} inputs and \overline{R} inputs of the set/reset-D-flip-flops SR-D-FF1 to SR-D-FF4 are inverted as shown in FIG. 12 by inverters that are disposed at gates of the respective inputs.

Besides, signals outputted from the respective \overline{Q} outputs of the set/reset-D-flip-flops SR-D-FF1 to SR-D-FF4 are also determined by the same operation as above.

Consequently, in this setting, a signal outputted from the NAND circuit NAND11, namely, the inverted value of the logical product of the output signals from respective \overline{Q} outputs is “1”, namely, a period of 15 cycles of the reference signal fs/R, and afterwards, it becomes “0”. This means that the count value M=15 setting is established at the programmable counter PC1.

[Operation of Charge Pump Circuit 2: FIG. 9]

Moreover, a detailed description will be given of the operation of the charge pump circuit 2 in the case where a timer signal flosw is inputted from the fast lock timer circuit 7 as above with the timing chart of FIG. 9. In the description of the timing chart, the count value M set at the programmable counter PC1 is 8 (M=8).

As is shown in FIG. 9, the current value I_{cp} [Ampere] of an output current signal Icp from the charge pump circuit 2 is switched in synchronization with a timer signal flosw from the fast lock timer circuit 7. That is, during a period when a timer signal flosw is on a high level (flosw=High), the switch SW1 at the charge pump circuit 2 is in an on-state (conducting state), and current supplied to the LPF 3 is set to a large value (I_{cp}=I₀+I₁). During a period when a timer signal flosw is on a low level (flosw=Low), the switch SW1 at the charge pump circuit 2 is in an off-state (shutoff state), and current supplied to LPF 3 is set to a small value (I_{cp}=I₀).

According to the operation, lock-up time is shortened in a period while a timer signal flosw is on a high level. Besides, a high C/N ratio is achieved in a period while a timer signal flosw is on a low level.

[Operation of Whole PLL Circuit]

Furthermore, a description will be given in detail of the frequency operation of a PLL circuit on the whole shown in FIG. 4 with reference to FIG. 9. As is shown in FIG. 9, in a PLL circuit according to the present embodiment, a channel setting for the frequency of the oscillation signal f0 to which the PLL circuit is to be tuned is switched from f₁ [Hz] to f₂ [Hz]. The fast lock timer circuit 7 resets a count number m of the programmable counter PC1 in synchronization with the switching timing according to the rising of an inputted enable signal Enable, and thereby starts a new count. On this occasion, a timer signal flosw is inputted to the switch SW1 at the charge pump circuit 2 as is described above, and the current value I_{cp} [Ampere] of an output current signal Icp from the charge pump circuit 2 is changed to a relatively large value (I_{cp}=I₀+I₁). Thus a dumping factor of the whole PLL circuit is changed to a relatively large value and the PLL circuit rapidly converges on a stable state, thus enabling a reduction in lock-up time of an oscillation signal f0 (switching its frequency to f₂ [Hz]).

Subsequently, since the PLL circuit is in a locked state after a period in which the fast lock timer circuit 7 is outputting a timer signal flows (timer period), the fast lock timer circuit 7 switches the level of the timer signal flosw to a low level to shut off the switch SW1 at the charge pump circuit 2. Thereby the current value I_{cp} [Ampere] of an output current signal Icp outputted from the charge pump circuit 2 is changed to a relatively small value. Consequently, the dumping factor of the whole PLL circuit is changed to a relatively small value and the PLL circuit operates so as to keep a stable state, thus enabling an improvement of the C/N characteristic of the whole PLL circuit.

[Effect of the First Embodiment]

Thanks to the structure and operation, a PLL circuit according to the present embodiment is capable of changing a timer setting of the fast lock timer circuit 7 freely at the time of switching channels (frequencies). Thus it is possible to control switching operation for a current value I_{cp} [Ampere] of an output current signal Icp from the charge pump circuit 2 on an arbitrary time base, that is, in an arbitrary time span. This means that according to the present embodiment, it is made possible to set lock-up time in an arbitrary time span, and also improve the C/N characteristic.

This is because, in this configuration, sufficient current is supplied to a capacitor included in the LPF 3 so as to accelerate lock-up time in association with fluctuation of loop gain in an unlocked state. That is, according to the present embodiment, it is possible to set an optimal dumping factor.

Moreover, in a PLL circuit according to the present embodiment, since the current value of current supplied to the LPF 3 can be switched on an arbitrary time base, it is possible to shorten lock-up time and improve the C/N characteristic unswayed by the setting of the filter constant for the LPF 3.

[Second Embodiment]

Next, the second embodiment of the present invention will be explained in detail with reference to the drawings. In the second embodiment, main basic structure is the same as that of the above first embodiment except that a new configuration is differently provided to the output end of an output signal flosw from the fast lock timer circuit 7 of the first embodiment, namely, the output end of the programmable counter PC1.

[Description of Structure]

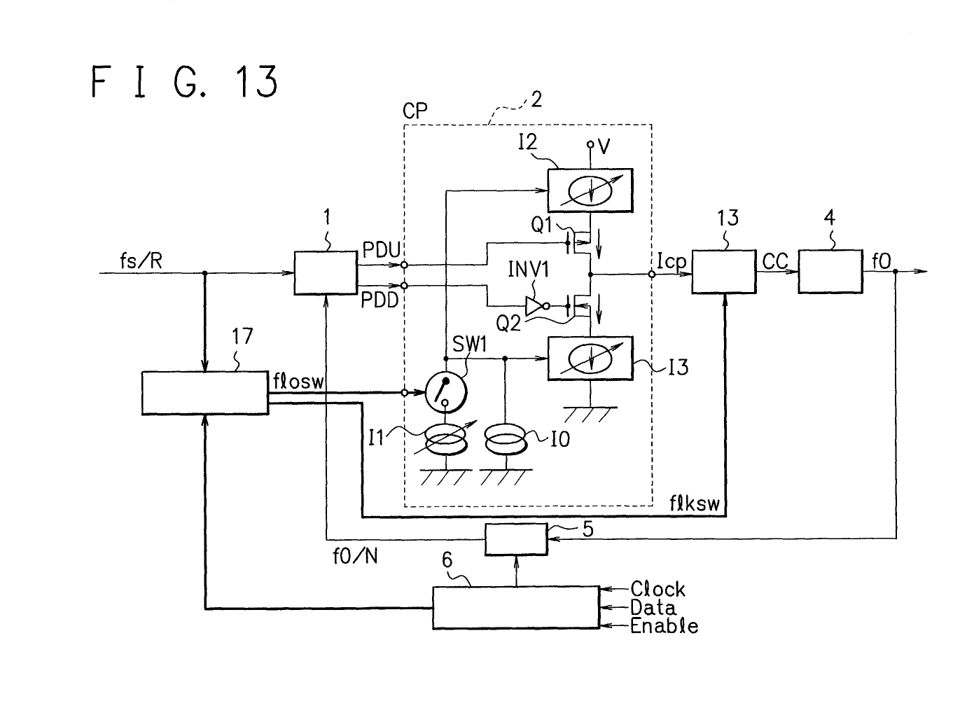

In the following, structure of a PLL circuit according to this embodiment will be explained in detail with reference to FIG. 13. FIG. 13 is a block diagram showing structure of a PLL circuit according to the embodiment.

Referring to FIG. 13, a PLL circuit according to the present embodiment comprises, similarly to a PLL circuit according to the first embodiment, a phase comparing detector (PD) 1, a charge pump circuit (CP) 2, a voltage control oscillator (VCO) 4, a programmable divider (1/N) 5, and a data interface 6. The structure and functions are the same as those in the first embodiment, and a detailed description will be avoided.

Additionally, as other constituents, there are provided a low-pass filter (LPF) 13 and a fast lock timer circuit 17, which are characteristics of the present embodiment. In the structure, a timer signal flosw outputted from the programmable counter PC 1 is utilized for generating a signal flksw (filter switching signal), which switches the filter constant in the LPF 13, at the fast lock timer circuit 17 and the LPF 13. Therefore, according to the second embodiment, the filter constant of the LPF 13 is switched before and after a lock- up state of a PLL circuit. Thus further reduction in lock-up time and a higher C/N ratio can be achieved in comparison with the first embodiment. The operation will be explained below in detail referring to the drawings.

[Structure of Fast Lock Timer Circuit 17]

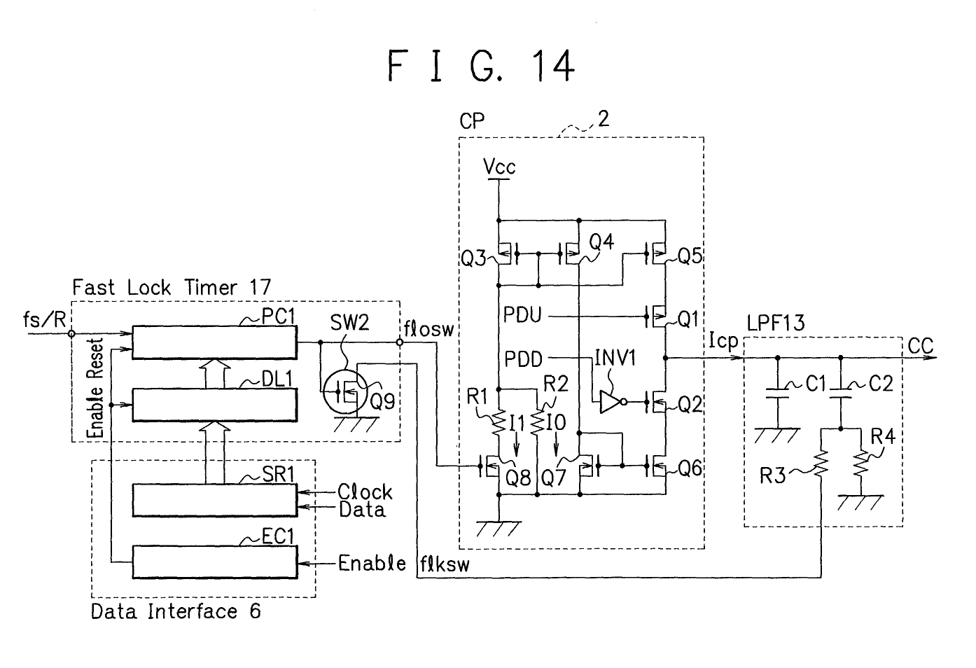

FIG. 14 shows the circuitry of the charge pump circuit 2, the LPF 13 and the fast lock timer circuit 17 according to the second embodiment. In the following, the circuitry of the fast lock timer circuit 17 will be explained.

Referring to FIG. 14, the fast lock timer circuit 17 according to the second embodiment includes a programmable counter PC1 and a data latch circuit DL1 similarly to the fast lock timer circuit of the first embodiment. The structure and operation of the programmable counter PC1 and the data latch circuit DL1 are the same as those in the first embodiment. Only the difference is that, in the present embodiment, an output stage of the programmable counter PC1, namely, the output of a timer signal flosw is divided in two. One is inputted to the switch SW1 of the charge pump circuit 2 (gate of N-MOSFET Q8) similarly to the first embodiment, the other is connected to a gate of the N-MOSFET Q9 newly disposed in the fast lock timer circuit 17.

Moreover, the source and drain of the N-MOSFET Q9 in the fast lock timer 17 are connected to a resister R3 included in the LPF 13 and a grounding wire (earth), respectively.

Consequently, according to this structure, the newly disposed N-MOSFET Q9 is in a conducting state during a period when a timer signal flosw is being outputted so that a filter signal flksw is generated. Thereby, according to the present embodiment, during a period when a timer signal flosw is being outputted, the filter characteristic of the LPF is changed, and thus realizing a reduction in lock-up time and improvement of the C/N characteristic.

[Phase Noise Characteristic]

The reason for changing the filter characteristic of the LPF 13 in the present embodiment will be explained in detail referring to the drawings.

Typically, there are the two most important parameters for deciding characteristics of a PLL circuit. One is loop-bandwidth. The other is phase margin. The both are parameters that determine the degree of stability of a PLL loop in the PLL circuit. The phase noise characteristic and the lock-up time characteristic, being characteristics of the PLL circuit, are also decided by the two parameters.

The phase noise characteristic is decided according to loop-bandwidth that is one of parameters for deciding the filter characteristic of the LPF 13. The loop-bandwidth can be changed relatively freely by changing configurations of the low-pass filter 13.

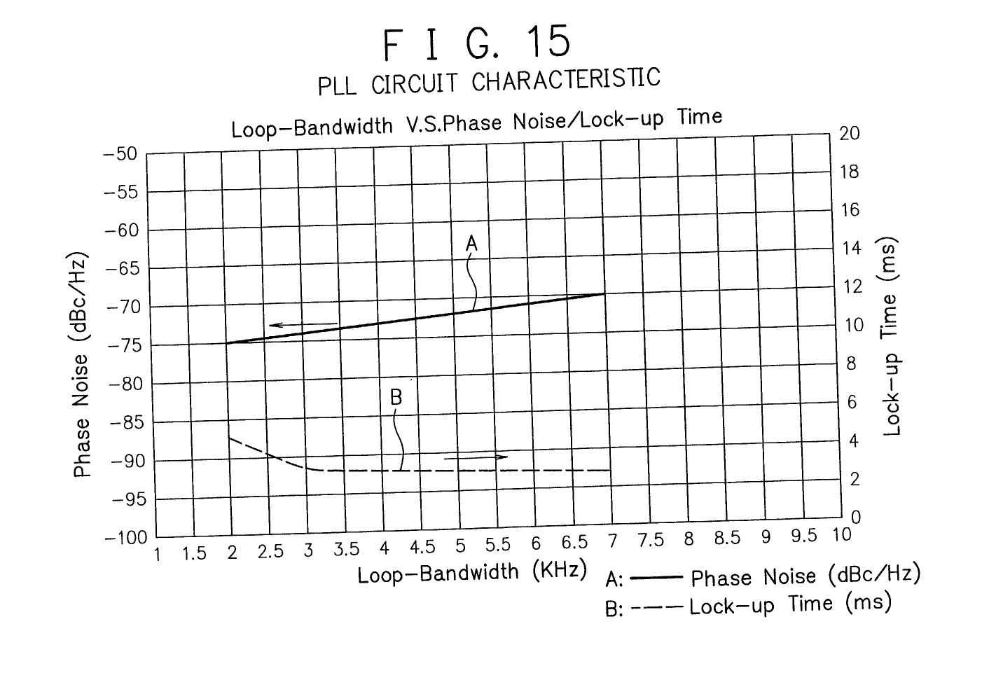

However, the phase noise characteristic and lock-up time show behaviors opposite to each other on the occasion of changing loop-bandwidth. This will be explained referring to FIG. 15. FIG. 15 is a graph showing anaclisis of the phase noise characteristic and lock-up time to the frequency of loop-bandwidth.

In FIG. 15, the loop-bandwidth [KHz] is indicated by a horizontal axis and the phase noise characteristic [dBc/Hz] and lock-up time [ms] are indicated by a vertical axis. In addition, line A expresses “Phase Noise VS Loop-Bandwidth”, while dotted line B expresses “Lock-up Time VS Loop-Bandwidth”.

As can be seen from FIG. 15, the phase noise characteristic shows more favorable value as loop-bandwidth is narrowed down, namely, as a frequency goes low. On the other hand, the lock-up time shows more favorable value as loop-bandwidth is broaden out, namely, as a frequency goes high.

Therefore, if a PLL circuit is configured so that the loop-bandwidth of the LPF 13 is to be narrow in order to improve the phase noise characteristic, lock-up time of the PLL circuit is prolonged. On the contrary, if a PLL circuit is configured so that the loop-bandwidth of the LPF 13 is to be wide in order to shorten lock-up time, the phase noise characteristic of the PLL circuit is deteriorated.

Consequently, in the structure according to the present embodiment, to resolve the above contradiction of antithetic characteristics, resisters and capacitors, which are connected in series with the LPF 13, are arranged in parallel to form a two-stage configuration, and loop-bandwidth is switched before and after PLL lock.

[Structure of Low-Pass Filter 13]

Referring to FIG. 14 showing the circuitry of the LPF 13 according to the present embodiment, the filter 13 includes two capacitors C1 and C2, and two resisters R3 and R4.

In this structure, one end of the capacitor C1, which is disposed on the side of the charge pump circuit 2 on the wiring, is connected to a wire in which an output current signal Icp is conducted, and the other end is connected to a ground (earth). Generally, a primary LPF possesses only the above constituents. In the present embodiment, however, another capacitor C2 is provided in parallel with the capacitor C1 in between the wire and the ground to form a secondary LPF.

One end of the capacitor C2 is connected to the wire in which an output current signal Icp is conducted similarly to that of the capacitor C1, and the other end is connected to the respective resisters R3 and R4, which are disposed in parallel between the capacitor C2 and the ground.

Besides, one end of the resister R4 is connected to the capacitor C2, and the other end is connected to the ground. On the other hand, one end of the resister R3 is connected to the capacitor C2, and the other end is connected to the drain side of the P-MOSFET Q9.

In this structure, the N-MOSFETQ9 is in a conducting state during a period in which a timer signal flosw is being outputted from the programmable counter PC1.

Accordingly, under the condition that the LPF 13 according to the present embodiment is in an unlocked state, since the N-MOSFETQ9 is in an on-state (conducting state) during a period when a timer signal flosw is on a high level (flosw=High), electric current is conducted in the resister R3 connected in parallel with the resister R4 in the LPF 13, and there is generated a filter switching signal flksw propagated via the resister R3. Thus a resistance value R of the whole LPF 13 is expressed as: R=(R3×R4)/(R3+R4) [Ω], and loop-bandwidth is set to be wide. In contrast thereto, under the condition that the LPF 13 is in a locked state, since the N-MOSFETQ9 is in an off-state (shutoff state) during a period when a timer signal flosw is on a low level (flosw=Low), the resister R3 is dead in the LPF 13. Thus a resistance value R of the LPF 13 is only R4, and loop-bandwidth is set to be narrow.

[Operation According to the Second Embodiment]

In the following, a description will be given in detail of the operation of a PLL circuit according to the second embodiment with reference to the drawings. Incidentally, in the description, the count value M, which is set at the programmable counter PC1 included in the fast lock timer circuit 17, is 8 (M=8).

In the present embodiment, a data signal Data, a clock signal Clock, an enable signal Enable (a reset signal Reset), a reference signal fs/R, and a signal “SRD-FF4 \overline{Q}” outputted from the \overline{Q} output of the set/reset-D-flip-flop SR-D-FF4 are the same as those in the first embodiment.

In such structure, a timer signal flosw is outputted from the programmable counter PC1 of the fast lock timer circuit 17 as “1” during a period of counting the reference signal fs/R eight times similarly to the first embodiment.

According to the second embodiment, the outputted timer signal flosw is inputted to the switch SW1 of the charge pump circuit 2 in the same manner as the first embodiment. Besides, at the same time, the timer signal flosw is inputted to the switch SW2 (N-MOSFETQ9) that is newly provided to the fast lock timer circuit 17 as well.

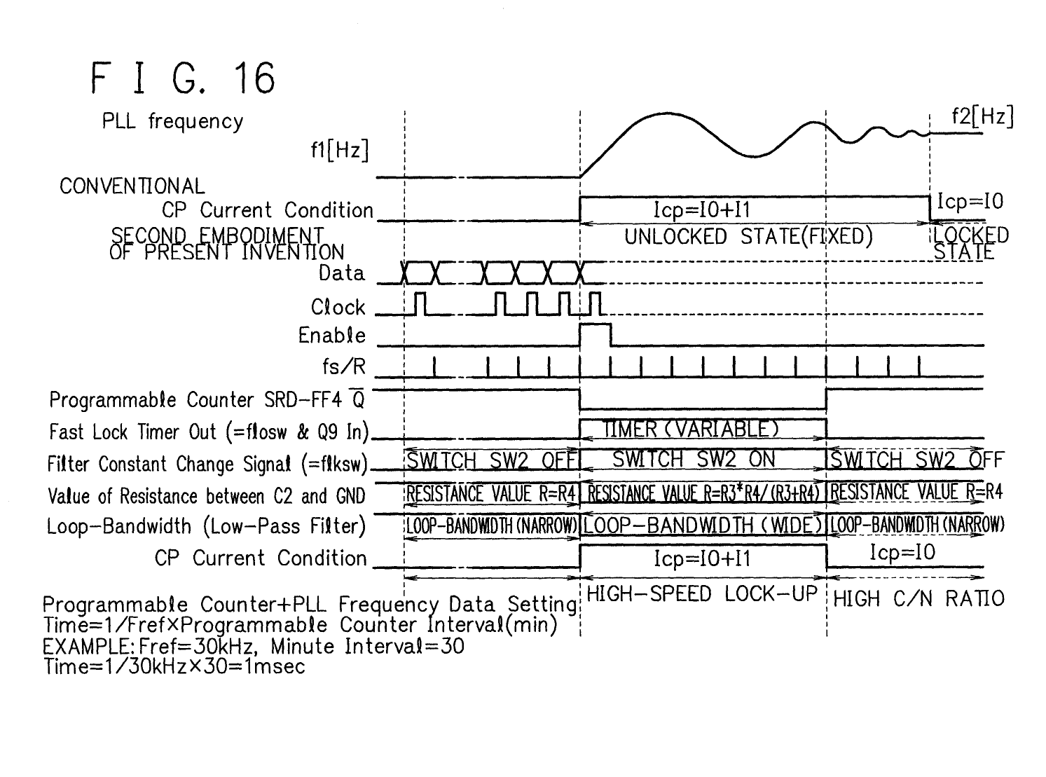

When a timer signal flosw is inputted to the gate of the N-MOSFETQ9 (switch SW2), the switch SW2 goes into an on-state (conducting state), and electric current is conducted in the resister R3. The signal conducted on this occasion is the filter switching signal flksw (“Filter Constant Change Signal” in FIG. 16). Additionally, since the resisters R3 and R4 are arranged in parallel between the capacitor C2 and the ground in the LPF 13, the resistance value R therebetween is expressed as: R=R3×R4/(R3+R4) (make reference to “Value of Resistance between C2 and GND” in FIG. 16). Incidentally, when the filter switching signal flksw is not outputted, the resistance value R between the capacitor C2 and the ground is a value of the resister R4, that is, R=R4. Consequently, in comparison between periods when the timer signal flosw is “1” and when it is “0”, the resistance value R between the capacitor C2 and the ground is smaller when the signal flosw is “1”.

When the resistance value R between the capacitor C2 and the ground becomes smaller as above, the time constant τ of the LPF 13 diminishes, and thereby loop-bandwidth is widened.

Therefore, as is shown in FIG. 15, during a period when a timer signal flosw is being outputted, the value of loop-bandwidth is relatively large. Thus lock-up time is shortened. On the other hand, during a period when a timer signal flosw is not being outputted, the value of loop-bandwidth is relatively small. Thus the favorable C/N characteristic can be obtained. This means that the second embodiment brings about further effects in comparison with the first embodiment.

As set forth hereinabove, in a PLL circuit in accordance with the first embodiment of the present invention, a time base can be changed freely by the timer setting of a fast lock timer circuit on the occasion of switching channels (frequencies). Thus switching operation for the current value supplied from a charge pump circuit can be controlled on an arbitrary time base.

Therefore, it is possible to supply sufficient electric current to a capacitor included in an LPF in association with a transition of loop gain in an unlocked state, and set an optimal damping factor.

Moreover, since a PLL circuit in accordance with the first embodiment is constituted so that a time base can be set freely, it is possible to accelerate lock-up time as well as perform fine adjustment regardless of the setting for the filter constant of an LPF.

Furthermore, in a PLL circuit in accordance with the second embodiment of the present invention, there is achieved an effect on improving the stability factor of a PLL loop, which is the most important parameter of a PLL circuit.

Furthermore, a PLL circuit in accordance with the present invention is not limited to a particular size, and may be, for example, packed on a single chip. In such the single-chip circuitry, a microcomputer for controlling the dividing ratio may be set up outside of the chip, or the microcomputer may as well be included in the chip.

While the preferred embodiments of the present invention has been described using specific terms, such description is for illustrative purposes only, and it is to be understood that changes and variations may be made without departing from the spirit or the scope of the following claims.

What is claimed is:

1. A PLL circuit comprising:
a phase comparing means which outputs phase difference signals on the basis of phase difference of inputted two signals;
a charge pump circuit which outputs an output current signal on the basis of the phase difference signals; and
a fast lock timer circuit which outputs a signal for switching a value of the output current signal outputted from the charge pump means, wherein:
the fast lock timer circuit outputs a timer signal for lock-up or lock to the charge pump in order to switch the value of the output current signal.

2. A PLL circuit comprising:
a phase comparing means which outputs phase difference signals on the basis of phase difference of inputted two signals;
a charge pump circuit which outputs an output current signal on the basis of the phase difference signals; and
a fast lock timer circuit which outputs a signal for switching a value of the output current signal outputted from the charge pump means, wherein:
the fast lock timer circuit outputs a timer signal for lock-up or lock to the charge pump in order to switch the value of the output current signal; and
an unlock period, which is a lock-up for obtaining a high C/N ratio, and a lock period for obtaining a high-speed lock-up are switched at arbitrary intervals on the basis of the value of the output current signal.

3. A PLL circuit comprising:
a phase comparing means which outputs phase difference signals on the basis of phase difference of inputted two signals;
a charge pump circuit which outputs an output current signal on the basis of the phase difference signals;
a fast lock timer circuit which outputs a signal for switching a value of the output current signal outputted from the charge pump means;
a low-pass filter; and
an oscillator control means, wherein:
the fast lock timer circuit outputs a timer signal for lock-up or lock to the charge pump in order to switch the value of the output current signal; and
the fast lock timer circuit switches the value of the output current signal outputted from the charge pump circuit at arbitrary intervals by counting a base signal divided according to an inputted dividing ratio setting data and obtains speeding up of a lock-up time and a high C/N ratio characteristic.

4. A PLL circuit comprising:
a phase comparing means which outputs phase difference signals on the basis of phase difference of inputted two signals;
a charge pump circuit which outputs an output current signal on the basis of the phase difference signals;
a fast lock timer circuit which outputs a signal for switching a value of the output current signal outputted from the charge pump means;
a data interface means which directs the fast lock timer means to switch the value of the output current signal on the basis of inputted data;
a voltage control oscillation means which outputs an oscillation signal on the basis of an oscillator control signal outputted from the low-pass filter; and
a programmable counter which divides the oscillation signal by an arbitrary dividing value, wherein:
an unlock period, which is a lock-up for obtaining a high C/N ratio, and a lock period for obtaining a high-speed lock-up are switched at arbitrary intervals on the basis of the value of the output current signal;
the fast lock timer circuit outputs a timer signal for lock-up or lock to the charge pump in order to switch the value of the output current signal; and
the fast lock timer means outputs a signal for switching the value of the output current value on the basis of the direction.

5. A PLL circuit comprising:
a phase comparing means which outputs phase difference signals on the basis of phase difference of inputted two signals;
a charge pump circuit which outputs an output current signal on the basis of the phase difference signals;
a fast lock timer circuit which outputs a signal for switching a value of the output current signal outputted from the charge pump means;
a low-pass filter;
an oscillator control means;
a data interface means which directs the fast lock timer means to switch the value of the output current signal on the basis of inputted data;
a voltage control oscillation means which outputs an oscillation signal on the basis of an oscillator control signal outputted from the low-pass filter; and
a programmable counter which divides the oscillation signal by an arbitrary dividing value, wherein:
the fast lock timer circuit outputs a timer signal for lock-up or lock to the charge pump in order to switch the value of the output current signal;
the fast lock timer circuit switches the value of the output current signal outputted from the charge pump circuit at arbitrary intervals by counting a base signal divided according to an inputted dividing ratio setting data and obtains speeding up of a lock-up time and a high C/N ratio characteristic; and
the fast lock timer means outputs a signal for switching the value of the output current value on the basis of the direction.

6. The PLL circuit as claimed in claim 1 wherein:
the charge pump includes a switch comprising an N-MOSFET; and
the timer signal is inputted into a gate of the N-MOSFET.

7. The PLL circuit as claimed in claim 1 wherein:
the charge pump includes a switch and connected two galvano static circuits in parallel;
one of the two galvano static circuits is connected to the switch in series;
the switch outputs current through at least one of the galvano static circuits on the basis of the timer signal;
the switch includes an N-MOSFET; and
the timer signal is inputted into a gate of the N-MOSFET.

8. The PLL circuit as claimed in claim 1 wherein;
the phase comparing means includes:
a plurality of first NAND circuits into which the inputted two signals are inputted, respectively;
a plurality of reset/set-flip-flops;
a second NAND circuit whose input side is connected to each output port of the first NAND circuits and each output port of the reset/set-flip-flops; and
a plurality of third NAND circuits whose input sides are connected to each output port of the first NAND circuits, each output port of the reset-set-flip-flops, and an output port of the second NAND circuit, wherein:
each output port of the third NAND circuits is connected to each input port of the first NAND circuits; and
two signals which are to be inputted into the charge pump are outputted from each output port of the third NAND circuits.

9. The PLL circuit as claimed in claim 2 wherein the dividing ratio setting data includes:
a clock signal for synchronizing with an external signal;
a data signal for specifying intervals of switching the current value of the output current signal; and
an enable signal for switching the current value of the output current signal.

10. The PLL circuit as claimed in claim 3 wherein:
the fast lock timer further includes a filter switching means which outputs a signal for switching prescribed loop-bandwidth of the low-pass filter; and
the low-pass filter includes a first filter means and a second filter means which are connected in parallel, wherein the signal outputted from the filter switching means is inputted into an input port of the second filter through a first resistor, the second filter means includes the first resistor, a second resistor and a capacitor, the first and second resistors are connected in parallel with the first filter means through the capacitor, the first and second resistors are connected to the capacitor in parallel, and the second resistor is grounded.

11. The PLL circuit as claimed in claim 3 wherein:
the fast lock timer further includes a filter switching means which outputs a signal for switching prescribed loop-bandwidth of the low-pass filter;
the low-pass filter includes a first filter means and a second filter means which are connected in parallel, wherein the signal outputted from the filter switching means is inputted into an input port of the second filter through a first resistor, the second filter means includes the first resistor, a second resistor and a capacitor, the first and second resistors are connected in parallel with the first filter means through the capacitor, the first and second resistors are connected to the capacitor in parallel, and the second resistor is grounded; and
the filter switching means switches the prescribed loop-bandwidth according as the current value of the output current signal is switched.

12. The PLL circuit as claimed in claim 3, wherein:
a data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the fast lock timer further includes a filter switching means which outputs a signal for switching prescribed loop-bandwidth of the low-pass filter; and
the low-pass filter includes a first filter means and a second filter means which are connected in parallel, wherein the signal outputted from the filter switching means is inputted into an input port of the second filter through a first resistor, the second filter includes the first resistor, a second resistor and a capacitor, the first and second resistors are connected in parallel with the first filter means through the capacitor, the first and second resistors are connected to the capacitor in parallel, and the second resistor is grounded.

13. The PLL circuit as claimed in claim 3, wherein:
a data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the fast lock timer further includes a filter switching means which outputs a signal for switching prescribed loop-bandwidth of the low-pass filter;
the low-pass filter includes a first filter means and a second filter means which are connected in parallel, wherein the signal outputted from the filter switching means is inputted into an input port of the second filter through a first resistor, the second filter includes the first resistor, a second resistor and a capacitor, the first and second resistors are connected in parallel with the first filter means through the capacitor, the first and second resistors are connected to the capacitor in parallel, and the second resistor is grounded; and
the filter switching means switches the prescribed loop-bandwidth according as the current value of the output current signal is switched.

14. The PLL circuit as claimed in claim 3 wherein:
the fast lock timer further includes a filter switching means which outputs a signal for switching prescribed loop-bandwidth of the low-pass filter;
the low-pass filter includes a first filter means and a second filter means which are connected in parallel, wherein the signal outputted from the filter switching means is inputted into an input port of the second filter through a first resistor, the second filter includes the first resistor, a second resistor and a capacitor, the first and second resistors are connected in parallel with the first filter means through the capacitor, the first and second resistors are connected to the capacitor in parallel, and the second resistor is grounded;
a programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S}0 in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit; and
an output from the third NAND circuit is inputted into the first NAND circuit.

15. The PLL circuit as claimed in claim 3 wherein:
the fast lock timer further includes a filter switching means which outputs a signal for switching prescribed loop-bandwidth of the low-pass filter;
the low-pass filter includes a first filter means and a second filter means which are connected in parallel, wherein the signal outputted from the filter switching means is inputted into an input port of the second filter through a first resistor, the second filter includes the first resistor, a second resistor and a capacitor, the first and second resistors are connected in parallel with the first filter means through the capacitor, the first and second resistors are connected to the capacitor in parallel, and the second resistor is grounded;
the filter switching means switches the prescribed loop-bandwidth according as the current value of the output current signal is switched;
a programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface;
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit; and
an output from the third NAND circuit is inputted into the first NAND circuit.

16. The PLL circuit as claimed in claim 4 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal; and
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted.

17. The PLL circuit as claimed in claim 4 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit; and
an output from the third NAND circuit is inputted into the first NAND circuit.

18. The PLL circuit as claimed in claim 4 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the charge pump includes a switch and two galvano static circuits connected in parallel;
one of the two galvano static circuits is connected to the switch in series; and
the switch outputs current through at least one of the galvano static circuits on the basis of the timer signal.

19. The PLL circuit as claimed in claim 4 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the charge pump includes a switch and two galvano static circuits connected in parallel;
one of the two galvano static circuits is connected to the switch in series; and
the switch outputs current through at least one of the galvano static circuits on the basis of the timer signal.

20. The PLL circuit as claimed in claim 4 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit; and
reset or latch for switching frequency of the base signal is specified on the basis of the enable signal.

21. The PLL circuit as claimed in claim 4, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit; and
an output from the third NAND circuit is inputted into the first NAND circuit.

22. The PLL circuit as claimed in claim 4, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit; and
the flip-flop circuits are set/reset-D- flip-flops.

23. The PLL circuit as claimed in claim 4, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the charge pump includes a switch and two galvano static circuits connected in parallel;
one of the two galvano static circuits is connected to the switch in series; and
the switch outputs current through at least one of the galvano static circuits on the basis of the timer signal.

24. The PLL circuit as claimed in claim 4, wherein:
the programmable counter has three inputs and one output, in which two inputs among the three inputs are for an enable signal input and the divided base signal input, including:
a plurality of pairs of NAND circuits and a plurality flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the flip-flop circuits are set/reset-D- flip-flops;
the charge pump includes a switch and two galvano static circuits connected in parallel;
one of the two galvano static circuits is connected to the switch in series; and
the switch outputs current through at least one of the galvano static circuits on the basis of the timer signal.

25. The PLL circuit as claimed in claim 4, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all Q outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the flip-flop circuits are set/reset-D- flip-flops; and
reset or latch for switching frequency of the base signal is specified on the basis of the enable signal.

26. The PLL circuit as claimed in claim 4, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the charge pump includes a switch and two galvano static circuits connected in parallel;
one of the two galvano static circuits is connected to the switch in series;
the switch outputs current through at least one of the galvano static circuits on the basis of the timer signal; and
reset or latch for switching frequency of the base signal is specified on the basis of the enable signal.

27. The PLL circuit as claimed in claim 4, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the flip-flop circuits are set/reset-D- flip-flops;
the charge pump includes a switch and two galvano static circuits connected in parallel;
one of the two galvano static circuits is connected to the switch in series;
the switch outputs current through at least one of the galvano static circuits on the basis of the timer signal; and
reset or latch for switching frequency of the base signal is specified on the basis of the enable signal.

28. The PLL circuit as claimed in claim 5 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal; and
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted.

29. The PLL circuit as claimed in claim 5 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit; and
an output from the third NAND circuit is inputted into the first NAND circuit.

30. The PLL circuit as claimed in claim 5 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the charge pump includes a switch and two galvano static circuits connected in parallel;
one of the two galvano static circuits is connected to the switch in series; and
the switch outputs current through at least one of the galvano static circuits on the basis of the timer signal.

31. The PLL circuit as claimed in claim 5 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the charge pump includes a switch and two galvano static circuits connected in parallel;
one of the two galvano static circuits is connected to the switch in series; and
the switch outputs current through at least one of the galvano static circuits on the basis of the timer signal.

32. The PLL circuit as claimed in claim 5 wherein:
the data interface means includes:
a shift register receiving a clock signal and synchronizing with an externally signal, inputting a data signal on the basis of the synchronization, and outputting the inputted data signal to the fast lock timer means; and
an enable counter specifying at least one part of the data signal outputted from the shift register, and further outputting a latch/reset signal which specifies a timing of switching the value of the output current signal;
the fast lock timer means includes:
a data latch means latching the inputted data signal on the basis of the latch/reset signal outputted form the enable counter means, and outputs at least one count value setting signal; and
a programmable counting means setting the count value on the basis of the at least one count value setting signal, counts a reference signal till the count value setting a start point as an input of the latch/reset signal, and outputs the timer signal for switching the current value of the output current signal until cycles of the count value are counted;
the programmable counter has three inputs and one output, in which two inputs among the three inputs are for an enable signal input and the divided base signal input, including:
a plurality of pairs of NAND circuits and a plurality flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit; and
reset or latch for switching frequency of the base signal is specified on the basis of the enable signal.

33. The PLL circuit as claimed in claim 5, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit; and
an output from the third NAND circuit is inputted into the first NAND circuit.

34. The PLL circuit as claimed in claim 5, wherein:
the programmable counter has three inputs and one output, in which two inputs among the three inputs are for an enable signal input and the divided base signal input, including:
a plurality of pairs of NAND circuits and a plurality flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit; and
the flip-flop circuits are set/reset-D- flip-flops.

35. The PLL circuit as claimed in claim 5, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the charge pump includes a switch and two galvano static circuits connected in parallel;
one of the two galvano static circuits is connected to the switch in series; and
the switch outputs current through at least one of the galvano static circuits on the basis of the timer signal.

36. The PLL circuit as claimed in claim 5, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the flip-flop circuits are set/reset-D-flip-flops;
the charge pump includes a switch and two galvano static circuits connected in parallel;
one of the two galvano static circuits is connected to the switch in series; and
the switch outputs current through at least one of the galvano static circuits on the basis of the timer signal.

37. The PLL circuit as claimed in claim 5, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the flip-flop circuits are set/reset-D- flip-flops; and
reset or latch for switching frequency of the base signal is specified on the basis of the enable signal.

38. The PLL circuit as claimed in claim 5, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the charge pump includes a switch and two galvano static circuits connected in parallel;
one of the two galvano static circuits is connected to the switch in series;
the switch outputs current through at least one of the galvano static circuits on the basis of the timer signal; and
reset or latch for switching frequency of the base signal is specified on the basis of the enable signal.

39. The PLL circuit as claimed in claim 5, wherein:
the programmable counter has three inputs and one output, in which two inputs among the three inputs are for an enable signal input and the divided base signal input, including:
a plurality of pairs of NAND circuits and a plurality of flip-flop circuits that are same number of the pairs of NAND circuits, set up on an input port of the enable signal from the data interface; and
a first NAND circuit and a second inversion circuit set up on an input port of the divided base signal through a first inversion circuit, wherein:
remaining one input among the three inputs is for a signal input from the data latch, which is inputted through one NAND circuit forming the pairs of NAND circuits set up on the input port of the enable signal;
the one output includes a third NAND circuit into which all \overline{Q} outputs of the flip-flops are inputted;
the enable signal and a branching signal of the divided base signal are inputted into each input of the pairs of NAND circuits, the signal from the data latch is inputted into the one NAND circuit forming each pairs of NAND circuits, and each output from the one NAND circuit forming each pairs of NAND circuits is inputted into remaining NAND circuits forming the pairs of NAND circuits;
each of the outputs from the one NAND circuit forming the pairs of NAND circuits branches, which is inputted into each \overline{S} in the flip-flops, each of the \overline{Q} outputs is branched, and the branched \overline{Q} output is inputted into each D in the flip-flops, each of the remaining \overline{Q} output is inputted into each Cp in a post flip-flop through a second NAND circuit in a second stage and a fourth inversion circuit in a fourth stage, the divided base signal from the first NAND circuit and the second inversion circuit is inputted into a CP in a flip-flop in a first stage through a third inversion circuit and a fourth inversion circuit in a fourth stage, which is set in a post stage of the third inversion circuit;
an output from the third NAND circuit is inputted into the first NAND circuit;
the flip-flop circuits are set/reset-D- flip-flops;
the charge pump includes a switch and two galvano static circuits connected in parallel;
one of the two galvano static circuits is connected to the switch in series;
the switch outputs current through at least one of the galvano static circuits on the basis of the timer signal; and
reset or latch for switching frequency of the base signal is specified on the basis of the enable signal.
